(19) United States
(12) Patent Application Publication
(10) Pub. No.: US 2024/0407171 A1
(43) Pub. Date: Dec. 5, 2024

(54) SEMICONDUCTOR DEVICE

(71) Applicant: SAMSUNG ELECTRONICS CO., LTD., Suwon-si (KR)

(72) Inventors: PYEONGWOO KIM, Suwon-si (KR); Changsup LEE, Suwon-si (KR); Seungwoo PAEK, Suwon-si (KR); Yunsun JANG, Suwon-si (KR)

(21) Appl. No.: 18/672,106

(22) Filed: May 23, 2024

(30) Foreign Application Priority Data
Jun. 2, 2023 (KR) 10-2023-0071901

(51) Int. Cl. H10B 43/40; G11C 16/04; H01L 25/065; H10B 41/10; H10B 41/27; H10B 41/35; H10B 41/41; H10B 43/10; H10B 43/27; H10B 43/35; H10B 80/00

(52) U.S. Cl. CPC H10B 43/40; G11C 16/0483; H01L 25/0652; H10B 41/10; H10B 41/27; H10B 41/35; H10B 41/41; H10B 43/10; H10B 43/27; H10B 43/35; H10B 80/00; H01L 2225/06506

(57) ABSTRACT

A semiconductor device including a peripheral circuit structure; and a cell structure stacked on the peripheral circuit structure and including a cell region, a connection region, and a peripheral circuit connection region, wherein the cell structure includes gate electrodes spaced apart from one another in a vertical direction in the cell region; a channel structure extending in the vertical direction through the gate electrodes, in the cell region, and including a first end and a second end opposite to the first end, the first end being proximate to the peripheral circuit structure; an insulating wall extending in the vertical direction at a boundary between the cell region and the connection region; and a common source layer connected to the second end of the channel structure in the cell region and having a portion arranged on a sidewall of the insulating wall.

### CROSS-REFERENCE TO RELATED APPLICATION

This application is based on and claims priority under 35 U.S.C. § 119 to Korean Patent Application No. 10-2023-0071901, filed on Jun. 2, 2023, in the Korean Intellectual Property Office, the disclosure of which is incorporated by reference herein in its entirety.

### BACKGROUND

### 1. Field

Embodiments relate to a semiconductor device.

### 2. Description of the Related Art

In an electronic system using data storage, a semiconductor device capable of storing high-capacity data may be. In one method of increasing data storage capacity of a semiconductor device, a semiconductor device including three-dimensionally arranged memory cells instead of two-dimensionally arranged memory cells has been considered. In addition, a semiconductor device has been proposed in which a part of the semiconductor device is formed on a first substrate, another part of the semiconductor device is formed on a second substrate, and the first substrate and the second substrate are bonded.

### SUMMARY

The embodiments may be realized by providing a semiconductor device including a peripheral circuit structure; and a cell structure stacked on the peripheral circuit structure and including a cell region, a connection region, and a peripheral circuit connection region, wherein the cell structure includes gate electrodes spaced apart from one another in a vertical direction in the cell region; a channel structure extending in the vertical direction through the gate electrodes, in the cell region, and including a first end and a second end opposite to the first end, the first end being proximate to the peripheral circuit structure; an insulating wall extending in the vertical direction at a boundary between the cell region and the connection region; and a common source layer connected to the second end of the channel structure in the cell region and having a portion arranged on a sidewall of the insulating wall.

The embodiments may be realized by providing a semiconductor device including a peripheral circuit structure; and a cell structure stacked on the peripheral circuit structure and including a cell region, a connection region, and a peripheral circuit connection region, wherein the cell structure includes gate electrodes apart from one another in a vertical direction in the cell region; a channel structure extending in the vertical direction through the gate electrodes, in the cell region, and including a first end and a second end opposite to the first end, the first end being arranged close to the peripheral circuit structure; an insulating wall extending in the vertical direction at a boundary between the cell region and the connection region, and having an external wall and an internal wall; a conductive base layer arranged in the connection region and the peripheral circuit connection region and contacting the external wall of the insulating wall; and a common source layer arranged in the cell region, connected to the second end of the channel structure, and having an edge portion arranged on the internal wall of the insulating wall.

The embodiments may be realized by providing a semiconductor device including a peripheral circuit structure; and a cell structure stacked on the peripheral circuit structure and including a cell region, a connection region, and a peripheral circuit connection region, wherein the cell structure includes gate electrodes apart from one another in a vertical direction in the cell region; a channel structure extending in the vertical direction through the gate electrodes, in the cell region, and including a first end and a second end opposite to the first end, the first end being arranged close to the peripheral circuit structure; a pad extending from the gate electrodes, in the connection region, and having a stepped shape; an insulating wall extending in the vertical direction at a boundary between the cell region and the connection region and having an external wall and an internal wall; a conductive base layer arranged in the connection region and the peripheral circuit connection region and contacting the external wall of the insulating wall; a common source layer arranged in the cell region, connected to the second end of the channel structure, and having an edge portion arranged on the internal wall of the insulating wall; a first plug extending in the vertical direction through the pad, in the connection region, and having a first end passing through the conductive base layer; and a first ring insulation pattern passing through the conductive base layer and a cover insulating layer, in the connection region, surrounding the first plug in a plan view, being apart from the first plug, and having an annular shape.

### BRIEF DESCRIPTION OF THE DRAWINGS

Features will be apparent to those of skill in the art by describing in detail exemplary embodiments with reference to the attached drawings in which:

FIG. 1 is a block diagram of a semiconductor device according to embodiments;

FIG. 2 is a circuit diagram illustrating a memory block according to embodiments;

FIG. 3 is a perspective view illustrating a representative configuration of a semiconductor device according to embodiments;

FIG. 4 is a plan layout diagram of the semiconductor device of FIG. 3;

FIG. 5 is an enlarged layout diagram of portion A of FIG. 4;

FIG. 6 is a cross-sectional view taken along lines B1-B1′ and B2-B2′ of FIG. 5;

FIG. 7 is an enlarged view of portion CX1 of FIG. 6;

FIG. 8 is an enlarged view of portion CX2 of FIG. 6;

FIG. 9 is a horizontal cross-sectional view at the first vertical level of FIG. 6;

FIG. 10 is a cross-sectional view of a semiconductor device according to embodiments;

FIG. 11 is a cross-sectional view of a semiconductor device according to embodiments;

FIG. 12 is a cross-sectional view of a semiconductor device according to embodiments;

FIG. 13 is a cross-sectional view of a semiconductor device according to embodiments;

FIG. 14 is a cross-sectional view of a semiconductor device according to embodiments;

FIG. 15 is a cross-sectional view of a semiconductor device according to embodiments;

FIG. 16 is an enlarged view of portion CX2 of FIG. 15;

FIG. 17 is a horizontal cross-sectional view at the first vertical level of FIG. 15;

FIG. 18 is a cross-sectional view of a semiconductor device according to embodiments;

FIG. 19 is a cross-sectional view of a semiconductor device according to embodiments;

FIG. 20 is an enlarged view of portion CX1 of FIG. 19;

FIG. 21 is an enlarged view of portion CX2 of FIG. 19;

FIGS. 22A to 32 are schematic diagrams of stages in a method of manufacturing a semiconductor device according to embodiments; Specifically, FIGS. 22A, 23 to 28, 29A, and 30 to 32 are cross-sectional views taken along lines B1-B1′ and B2-B2′ of FIG. 6, FIG. 22B is a plan view of FIG. 22A, and FIG. 29B is an enlarged view of portion CX1 of FIG. 29A;

FIGS. 33A to 39 are cross-sectional views of stages in a method of manufacturing a semiconductor device according to embodiments;

FIG. 40 is a diagram schematically illustrating a data storage system including a semiconductor device according to embodiments;

FIG. 41 is a perspective view schematically illustrating a data storage system including a semiconductor device according to embodiments; and

FIG. 42 is a cross-sectional view schematically illustrating a semiconductor package according to embodiments.

### DETAILED DESCRIPTION

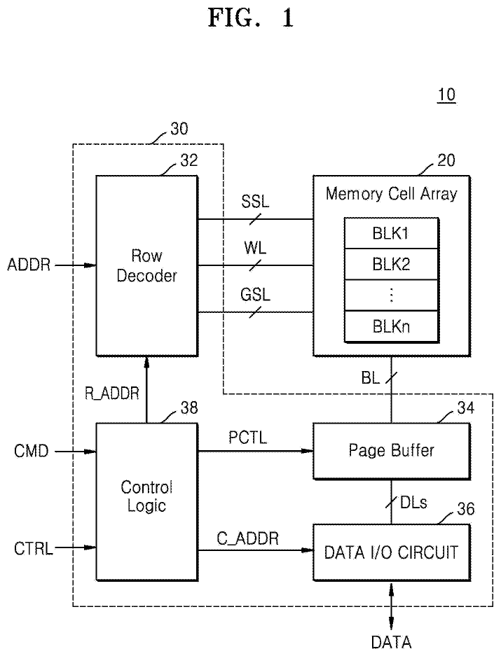

FIG. 1 is a block diagram of a semiconductor device 10 according to embodiments.

Referring to FIG. 1, the semiconductor device 10 may include a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, and a control logic 38. Although not shown in FIG. 1, the peripheral circuit 30 may further include an input/output interface, a column logic, a voltage generator, a pre-decoder, a temperature sensor, a command decoder, an address decoder, or an amplifier circuit.

The memory cell array 20 may be connected to the page buffer 34 through the bit line BL, and may be connected to the row decoder 32 through the word line WL, the string selection line SSL, and the ground selection line GSL. In the memory cell array 20, each of the plurality of memory cells included in each of the plurality of memory cell blocks BLK1, BLK2, . . . , and BLKn may be a flash memory cell. The memory cell array 20 may include a three-dimensional (3D) memory cell array. The 3D memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10, and may transmit and receive data DATA to and from a device outside the semiconductor device 10.

The row decoder 32 may select at least one of the plurality of memory cell blocks BLK1, BLK2, . . . , and BLKn in response to the address ADDR from the outside, and may select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to detect the data DATA stored in the memory cell array 20. The page buffer 34 may operate according to a control signal PCTL provided from the control logic 38.

The data input/output circuit 36 may be connected to the page buffer 34 through data lines DLs. The data input/output circuit 36 may receive the data DATA from a memory controller during the program operation and may provide program data DATA to the page buffer 34 based on a column address C_ADDR provided from the control logic 38. The data input/output circuit 36 may provide read data DATA stored in the page buffer 34 to the memory controller based on the column address C_ADDR provided from the control logic 38 during the read operation.

The data input/output circuit 36 may transmit an input address or command to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R ADDR to the row decoder 32, and may provide the column address C_ADDR to the data input/output circuit 36. The control logic 38 may generate various internal control signals used by the semiconductor device 10 in response to the control signal CTRL. For example, the control logic 38 may control a voltage level provided to the word line WL and the bit line BL when a memory operation such as the program operation or an erase operation is performed.

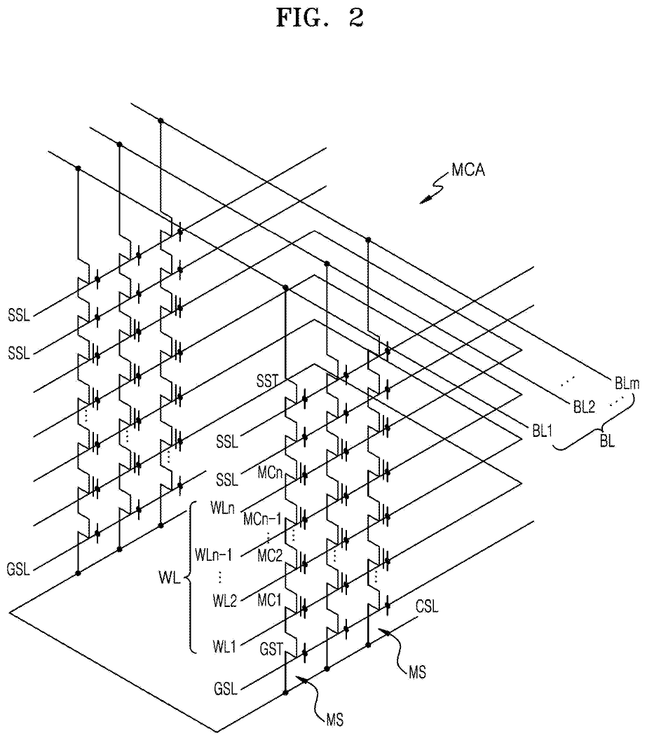

FIG. 2 is a circuit diagram illustrating a memory block BLK according to embodiments.

Referring to FIG. 2, a memory cell array MCA may include a plurality of memory cell strings MS. The memory cell array MCA may include a plurality of bit lines BL: BL1, BL2, . . . , and BLm, a plurality of word lines WL: WL1, WL2, . . . , WLn−1, and WLn, at least one string selection line SSL, at least one ground selection line GSL, and a common source line CSL. A plurality of memory cell strings MS may be formed between the plurality of bit lines BL: BL1, BL2, . . . , and BLm and the common source line CSL. It is illustrated in FIG. 2 that each of the plurality of memory cell strings MS includes two string selection lines SSL. In an implementation, each of the plurality of memory cell strings MS may include one string selection line SSL.

Each of the plurality of memory cell strings MS may include a string selection transistor SST, a ground selection transistor GST, and a plurality of memory cell transistors MC1, MC2, MCn−1, and MCn. A drain region of the string selection transistor SST may be connected to the plurality of bit lines BL: BL1, BL2, . . . , and BLm and a source region of the ground selection transistor GST may be connected to the common source line CSL. The common source line CSL may be a region to which source regions of a plurality of ground selection transistors GST are commonly connected.

The string selection transistor SST may be connected to the string selection line SSL, and the ground selection transistor GST may be connected to the ground selection line GSL. The plurality of memory cell transistors MC1, MC2, . . . , MCn−1, and MCn may be connected to the plurality of word lines WL: WL1, WL2, . . . , WLn−1, and WLn, respectively.

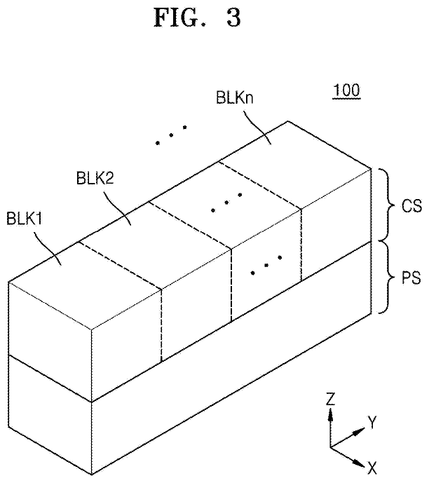

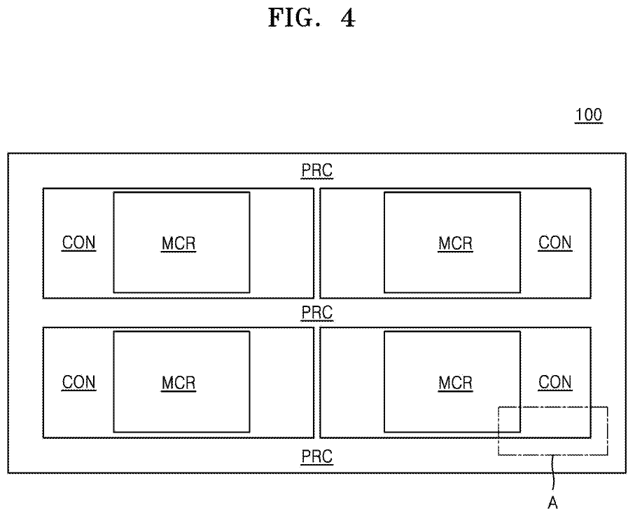

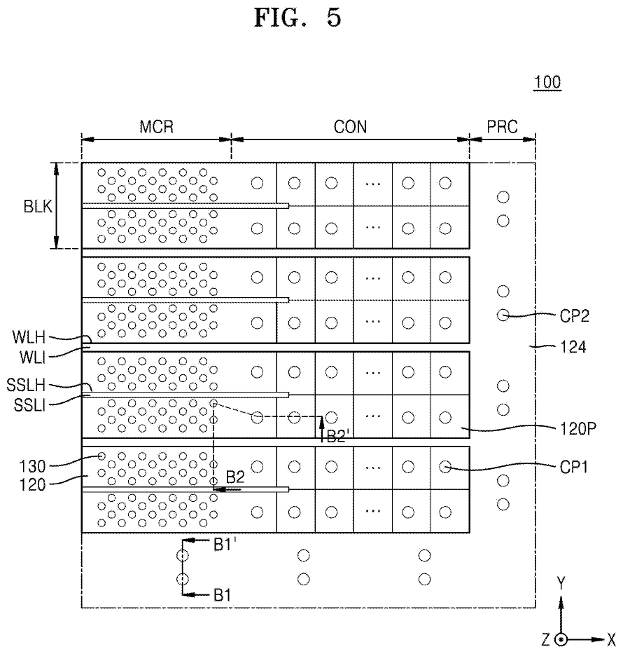

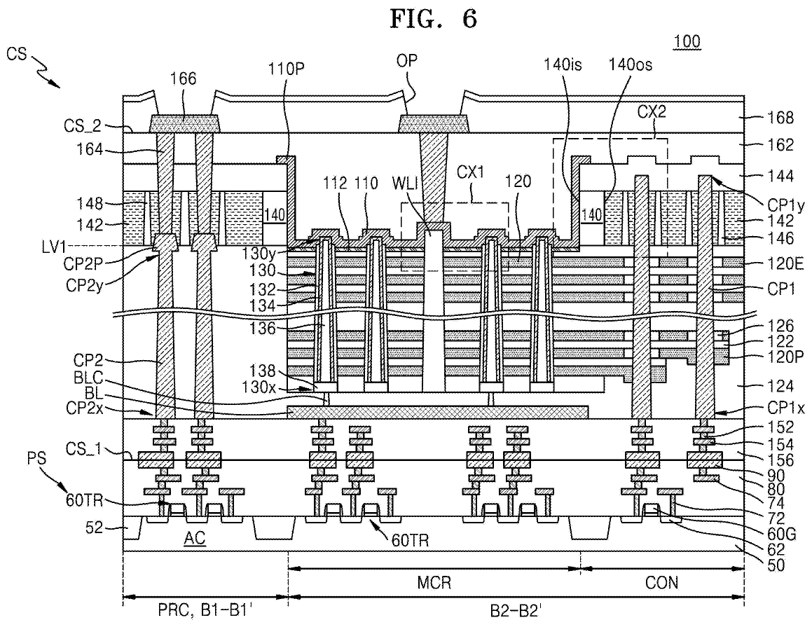

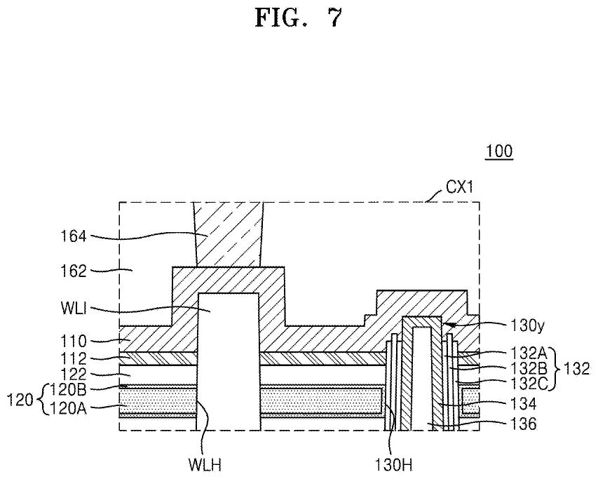

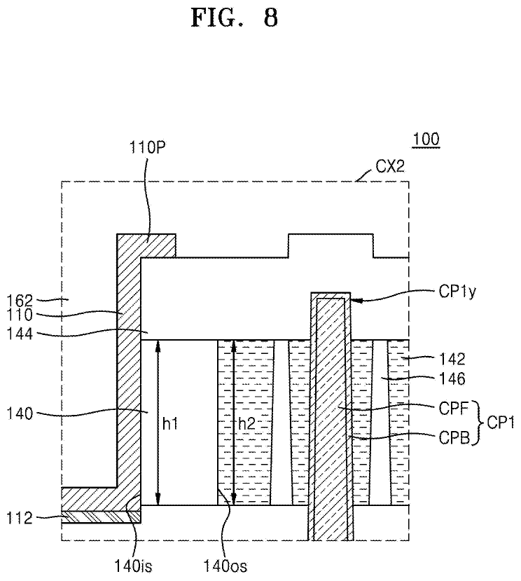

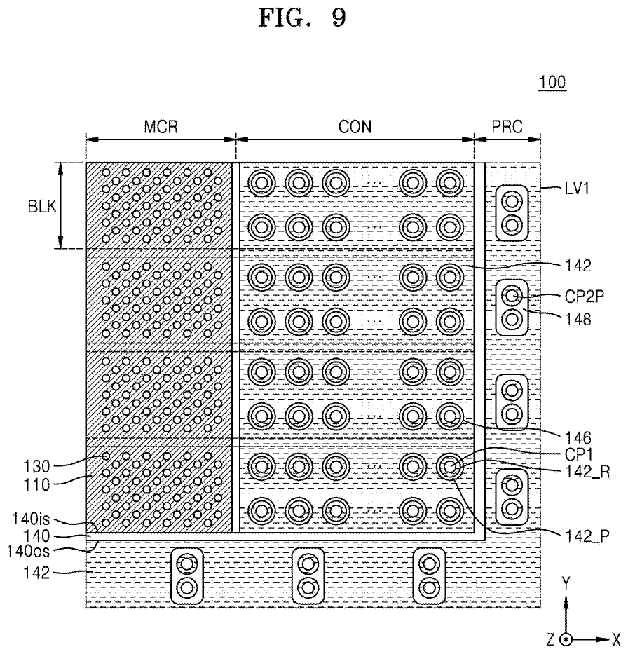

FIG. 3 is a perspective view illustrating a representative configuration of a semiconductor device 100 according to embodiments. FIG. 4 is a plan layout diagram of the semiconductor device 100, and FIG. 5 is an enlarged layout diagram of the portion A of FIG. 4. FIG. 6 is a cross-sectional view taken along the lines B1-B1′ and B2-B2′ of FIG. 5. FIG. 7 is an enlarged view of the portion CX1 of FIG. 6, and FIG. 8 is an enlarged view of the portion CX2 of FIG. 6. FIG. 9 is a horizontal cross-sectional view at the first vertical level LV1 of FIG. 6.

Referring to FIGS. 3 to 9, the semiconductor device 100 includes a cell structure CS and a peripheral circuit structure PS overlapping each other in a vertical direction Z. The cell structure CS may include the memory cell array 20 described with reference to FIG. 1, and the peripheral circuit structure PS may include the peripheral circuit 30 described with reference to FIG. 1.

The cell structure CS may include the plurality of memory cell blocks BLK1, BLK2, . . . , and BLKn. Each of the plurality of memory cell blocks BLK1, BLK2, . . . , and BLKn may include three-dimensionally arranged memory cells.

The peripheral circuit structure PS may include a plurality of peripheral circuit transistors 60TR and a peripheral circuit wiring structure 70 arranged on a substrate 50. In the substrate 50, an active region AC may be defined by a device isolation layer 52 and the plurality of peripheral circuit transistors 60TR may be formed on the active region AC. Each of the plurality of peripheral circuit transistors 60TR may include a peripheral circuit gate 60G and a source/drain region 62 arranged in a part of the substrate 50 on both sides of the peripheral circuit gate 60G.

The substrate 50 may include a semiconductor material, e.g., a group IV semiconductor, a group III-V compound semiconductor, or a group II-VI compound semiconductor. For example, the group IV semiconductor may include silicon (Si), germanium (Ge), or silicon germanium (SiGe). The substrate 50 may be a bulk wafer or an epitaxial layer. In an implementation, the substrate 50 may include a silicon-on-insulator (SOI) substrate or a germanium-on-insulator (GeOI) substrate.

The peripheral circuit wiring structure 70 includes a plurality of peripheral circuit contacts 72 and a plurality of peripheral circuit wiring layers 74. An interlayer insulating layer 80 covering the plurality of peripheral circuit transistors 60TR and the peripheral circuit wiring structure 70 may be arranged on the substrate 50. A plurality of peripheral circuit wiring layers 74 may have a multilayer structure including a plurality of metal layers at different vertical levels. A plurality of connection pads 90 may be on the interlayer insulating layer 80, and the peripheral circuit structure PS and the cell structure CS may be electrically connected and bonded to each other by the plurality of connection pads 90.

The cell structure CS may include a cell region MCR, a connection region CON, and a peripheral circuit connection region PRC. A memory cell block BLK including a plurality of memory cell strings extending in the vertical direction Z may be arranged in the cell region MCR. A common source layer 110, a plurality of gate electrodes 120, and a channel structure 130 extending in the vertical direction Z through the plurality of gate electrodes 120 and connected to the common source layer 110 may be arranged in the cell region MCR. A plurality of extensions 120E and a plurality of pads 120P connected to the plurality of gate electrodes 120 and a plurality of first plugs CP1 electrically connected to the plurality of pads 120P through the plurality of extensions 120E and the plurality of pads 120P may be arranged in the connection region CON. A second plug CP2 extending in the vertical direction Z and electrically connected to the peripheral circuit wiring structure 70 may be in the peripheral circuit connection region PRC.

The cell structure CS may include a first surface CS_1 connected to the peripheral circuit structure PS, and a second surface CS_2 opposite to the first surface CS_1. In FIG. 6, it is illustrated that the first surface CS_1 of the cell structure CS is arranged at a lower side of the cell structure CS and the second surface CS_2 of the cell structure CS is arranged at an upper side of the cell structure CS. Here, for convenience sake, as illustrated in FIG. 6, being arranged closer to the first surface CS_1 of the cell structure CS is referred to as being arranged at a lower vertical level, and being arranged closer to the second surface CS_2 of the cell structure CS is referred to as being arranged at a higher vertical level.

In the cell region MCR, the plurality of gate electrodes 120 may be apart from one another in the vertical direction Z and may alternate with a plurality of mold insulating layers 122. The plurality of gate electrodes 120 may extend to the connection region CON, and parts of the plurality of gate electrodes 120 arranged in the connection region CON may be referred to as the plurality of extensions 120E. The plurality of extensions 120E may have horizontal lengths gradually increasing toward the second surface CS_2 of the cell structure CS (that is, upward in FIG. 6). The plurality of extensions 120E may have a stepped shape, and the plurality of pads 120P may be connected to ends of the plurality of extensions 120E. Each of the plurality of pads 120P may have a thickness greater than that of each of the plurality of extensions 120E in the vertical direction Z.

As illustrated in FIG. 7, each of the plurality of gate electrodes 120 may include a buried conductive layer 120A and a conductive barrier layer 120B surrounding a top surface, a bottom surface, and side surfaces of the buried conductive layer 120A. In an implementation, the buried conductive layer 120A may include a metal such as tungsten (W), nickel (Ni), cobalt (Co), or tantalum (Ta), a metal silicide such as tungsten silicide, nickel silicide, cobalt silicide, or tantalum silicide, doped polysilicon, or a combination thereof. In some embodiments, the conductive barrier layer 120B may include titanium nitride, tantalum nitride, tungsten nitride, or a combination thereof.

In an implementation, the plurality of gate electrodes 120 may correspond to the ground selection line GSL, the plurality of word lines WL: WL1, WL2, . . . , WLn−1, and WLn, and the at least one string selection line SSL constituting the memory cell string MS (refer to FIG. 2). In an implementation, the uppermost gate electrode 120 may function as the ground selection line GSL, the lowermost two gate electrodes 120 may function as the string selection lines SSL, and the remaining gate electrodes 120 may function as the word lines WL. Accordingly, the memory cell string MS, in which the ground selection transistor GST, the string selection transistor SST, and the plurality of memory cell transistors MC1, MC2, MCn−1, and MCn between the ground selection transistor GST and the string selection transistor SST are serially connected to one another, may be provided. In an implementation, at least one gate electrode of the plurality of gate electrodes 120 may function as a dummy word line.

A stack isolation insulating layer WLI may be arranged in a stack isolation opening WLH extending in the vertical direction Z through the plurality of gate electrodes 120 and the plurality of mold insulating layers 122. The stack isolation insulating layer WLI may have a top surface at a vertical level higher than the uppermost gate electrode 120, and may protrude upward based on the uppermost gate electrode 120. As illustrated in FIG. 5, the gate electrodes 120 arranged between a pair of stack isolation openings WLH may form a block BLK. In an implementation, at least one gate electrode 120 (e.g., the lowermost gate electrode 120) may be divided into two gate electrodes 120 by a string isolation opening SSLH in one block BLK. A string isolation insulating layer SSLI may be arranged in the string isolation opening SSLH.

In the connection region CON and the peripheral circuit connection region PRC, a stack insulating layer 124 may surround the plurality of gate electrodes 120, the plurality of extensions 120E, and the plurality of pads 120P. In a plan view, the stack insulating layer 124 may surround the plurality of gate electrodes 120, and may have a top surface at the same level as the uppermost gate electrode 120 in the peripheral circuit connection region PRC.

The channel structure 130 may include a first end 130x close or proximate to the peripheral circuit structure PS and a second end 130y opposite to the first end 130x. In an implementation, the channel structure 130 may have an inclined sidewall such that a width of the first end 130x is greater than that of the second end 130y. A bit line BL may be electrically connected to the first end 130x of the channel structure 130 through a bit line contact BLC, and the common source layer 110 may be connected to the second end 130y of the channel structure 130.

The channel structure 130 may be in a channel hole 130H extending (e.g., lengthwise) in the vertical direction through the plurality of gate electrodes 120 and the plurality of mold insulating layers 122, and may include a gate insulating layer 132, a channel layer 134, a buried insulating layer 136, and a drain region 138. The channel layer 134 may be cylindrical, the gate insulating layer 132 may be on an external wall of the channel layer 134, and the buried insulating layer 136 may be on an internal wall of the channel layer 134. The gate insulating layer 132 may not be on the uppermost surface of the channel layer 134, e.g., on a top surface of the channel layer 134 on the second end 130y of the channel structure 130.

As illustrated in FIG. 7, the gate insulating layer 132 may have a structure including a tunneling dielectric layer 132A, a charge storage layer 132B, and a blocking dielectric layer 132C sequentially arranged on the external wall of the channel layer 134. Relative thicknesses of the tunneling dielectric layer 132A, the charge storage layer 132B, and the blocking dielectric layer 132C constituting the gate insulating layer 132 may be variously modified.

The tunneling dielectric layer 132A may include silicon oxide, hafnium oxide, aluminum oxide, zirconium oxide, or tantalum oxide. The charge storage layer 132B may be a region in which electrons passing through the tunneling dielectric layer 132A from the channel layer 134 may be stored and may include silicon nitride, boron nitride, silicon boron nitride, or polysilicon doped with impurities. The blocking dielectric layer 132C may include silicon oxide, silicon nitride, or metal oxide having a greater dielectric constant than silicon oxide. The metal oxide may include hafnium oxide, aluminum oxide, zirconium oxide, tantalum oxide, or a combination thereof.

An etch stop layer 112 may be on the uppermost gate electrode 120, and may include polysilicon. In an implementation, the etch stop layer 112 may be omitted.

The common source layer 110 may be connected to the second end 130y of the channel structure 130 on the etch stop layer 112 and may be conformally formed to cover a top surface of the stack isolation insulating layer WLI. In a plan view, the common source layer 110 may be arranged on an entire region of the cell region MCR. A part of the common source layer 110 in contact with the etch stop layer 112 may have a top surface at a different vertical level from a part of the common source layer 110 in contact with the second end 130y of the channel structure 130. In an implementation, a part of the common source layer 110 in contact with the stack isolation insulating layer WLI may have a top surface at a different vertical level from a part of the common source layer 110 in contact with the second end 130y of the channel structure 130.

In an implementation, the common source layer 110 may include polysilicon, and a laser annealing process may be performed on the common source layer 110 to have a relatively large grain size and/or relatively high crystal quality. In an implementation, when the laser annealing process is performed on the common source layer 110, the etch stop layer 112 is crystallized together, so that the etch stop layer 112 may also have a relatively large grain size and/or relatively high crystal quality. In an implementation, at least a part of a physical boundary between the etch stop layer 112 and the common source layer 110 may not be identifiable after the laser annealing process is performed.

In an implementation, as illustrated in FIG. 7, the common source layer 110 may conformally cover the top surface of the channel layer 134 and a top surface of the gate insulating layer 132. In an implementation, the gate insulating layer 132 may be at a lower level than the top surface of the channel layer 134, so that the top surface and a part of a sidewall of the channel layer 134 may be covered with the common source layer 110 and a sufficient contact area may be secured between the channel layer 134 and the common source layer 110. In an implementation, as illustrated in FIG. 7, the charge storage layer 132B may be arranged such that a top surface thereof protrudes upward from top surfaces of the tunneling dielectric layer 132A and the blocking dielectric layer 132C. In an implementation, the top surface of the charge storage layer 132B may be at the same level as the top surfaces of the tunneling dielectric layer 132A and the blocking dielectric layer 132C, so that the gate insulating layer 132 may have a flat horizontal level.

An insulating wall 140 may be at a boundary between the cell region MCR and the connection region CON. The insulating wall 140 may surround the cell region MCR in a plan view, and may have a top surface at a vertical level higher than the uppermost gate electrode 120. The insulating wall 140 may have a relatively large first height h1, e.g., the first height h1 of the insulating wall 140 may be in a range of 50 nanometers to 1,000 nanometers. In an implementation, the insulating wall 140 may include a silicon oxide layer, a silicon nitride layer, SiON, SiOCN, SiCN, or a combination thereof.

A conductive base layer 142 may be in the connection region CON and the peripheral circuit connection region PRC. The conductive base layer 142 may be formed to the same second height h2 as the insulating wall 140. In an implementation, the second height h2 of the conductive base layer 142 may be in a range of 50 nanometers to 1,000 nanometers. The conductive base layer 142 may surround the insulating wall 140 in a plan view, and may contact an external wall 140os of the insulating wall 140. In an implementation, the conductive base layer 142 may include polysilicon.

A cover insulating layer 144 may be on the insulating wall 140 and the conductive base layer 142 in the connection region CON and the peripheral circuit connection region PRC. The cover insulating layer 144 may be on the connection region CON and the peripheral circuit connection region PRC excluding the cell region MCR. The cover insulating layer 144 may be formed to a height in a range of 50 nanometers to 300 nanometers. In an implementation, the cover insulating layer 144 may include a silicon oxide layer, a silicon nitride layer, SiON, SiOCN, SiCN, or a combination thereof. In an implementation, the cover insulating layer 144 may include a reflective layer having a stacked structure of alternately arranged silicon oxide layers and silicon nitride layers.

In an implementation, the cover insulating layer 144 may cover the insulating wall 140 and the conductive base layer 142 and function as an insulation barrier preventing heat caused by a laser from being transferred to a lower structure in the connection region CON and the peripheral circuit connection region PRC when the laser annealing process of the common source layer 110 is performed.

As illustrated in FIG. 8, an edge portion 110P of the common source layer 110 may be on an internal wall 140 is of the insulating wall 140 and may extend onto a top surface of the cover insulating layer 144. Accordingly, a large vertical level difference may occur between the central portion of the common source layer 110 and the edge portion 110P of the common source layer 110.

In the connection region CON, the first plug CP1 may be arranged through the plurality of extensions 120E and the plurality of pads 120P extending from the plurality of gate electrodes 120. A plurality of insulation patterns 126 may vertically overlap the plurality of pads 120P connected to the first plug CP1, and may be between the first plug CP1 and the plurality of extensions 120E.

In an implementation, a first end CP1x of the first plug CP1 may be adjacent to the peripheral circuit structure PS, and a second end CP1y of the first plug CP1 may be opposite to the first end CP1x. The first plug CP1 may have a sidewall inclined so that a width of the first end CP1x is greater than that of the second end CP1y. The second end CP1y of the first plug CP1 may extend through the conductive base layer 142, and a top surface of the second end CP1y of the first plug CP1 may be covered with the cover insulating layer 144.

In an implementation, the first plug CP1 may include a conductive filling layer CPF and a thin barrier layer CPB surrounding a top surface and a sidewall of the conductive filling layer CPF. In an implementation, the conductive filling layer CPF may include a metal such as tungsten (W), nickel (Ni), cobalt (Co), or tantalum (Ta), metal silicide such as tungsten silicide, nickel silicide, cobalt silicide, or tantalum silicide, doped polysilicon, or a combination thereof. The barrier layer CPB may include titanium nitride, tantalum nitride, tungsten nitride, or a combination thereof.

In an implementation, a first ring insulation pattern 146 may be arranged around the first plug CP1 to surround the first plug CP1 through the conductive base layer 142 while being apart from the first plug CP1. The first ring insulation pattern 146 may have a top surface at the same level as a top surface of the conductive base layer 142 and a bottom surface at the same level as a bottom surface of the conductive base layer 142, and may be formed to the same height as the conductive base layer 142.

The first plug CP1 may be electrically connected to a ring 142_R of the conductive base layer 142 passing through the conductive base layer 142 and adjacent to the first plug CP1. The first ring insulation pattern 146 may physically separate and/or electrically insulate the ring 142_R of the conductive base layer 142 adjacent to the first plug CP1 from the remaining part of the conductive base layer 142.

In the peripheral circuit connection region PRC, the second plug CP2 may be arranged through the stack insulating layer 124. A first end CP2x of the second plug CP2 may be adjacent to the peripheral circuit structure PS, and a second end CP2y of the second plug CP2 may be opposite to the first end CP2x. The second plug CP2 may have a sidewall inclined so that a width of the first end CP2x is greater than that of the second end CP2y. The second end CP2y of the second plug CP2 may contact a landing pad CP2P, and at least a part of the landing pad CP2P may be covered with the conductive base layer 142.

In an implementation, a second ring insulation pattern 148 may be arranged around the landing pad CP2P to surround the landing pad CP2P through the conductive base layer 142 while being apart from the landing pad CP2P. The second ring insulation pattern 148 may physically separate and/or electrically insulate the ring 142_R of the conductive base layer 142 adjacent to the landing pad CP2P from the remaining part of the conductive base layer 142. In an implementation, as illustrated in FIG. 9, two landing pads CP2P may be arranged side by side, and the second ring insulation pattern 148 may surround each of the landing pads CP2P and has a merged planar shape. In an implementation, one second ring insulation pattern 148 may be arranged around one landing pad CP2P.

Between the stack insulating layer 124 and the peripheral circuit structure PS, a connection via 152, a connection wiring layer 154, and an interlayer insulating layer 156 surrounding the connection via 152 and the connection wiring layer 154 may be arranged. The connection via 152 and the connection wiring layer 154 may be multi-layered to be at a plurality of vertical levels, and may electrically connect the bit line BL, the first plug CP1, and the second plug CP2 to the peripheral circuit structure PS through the plurality of connection pads 90.

An upper interlayer insulating layer 162 may be on the common source layer 110 and the cover insulating layer 144, rear vias 164 may be arranged through the upper interlayer insulating layer 162, and rear pads 166 may be arranged on the upper interlayer insulating layer 162. At least one of the rear vias 164 may be connected to a top surface of the common source layer 110 through the upper interlayer insulating layer 162 in the cell region MCR, and at least one other of the rear vias 164 may extend to the conductive base layer 142 through the upper interlayer insulating layer 162 and the cover insulating layer 144 in the peripheral circuit connection region PRC and may be connected to the landing pad CP2P. The rear pads 166 may be connected to the rear vias 164. A passivation layer 168 may be arranged on the upper interlayer insulating layer 162, and an opening OP of the passivation layer 168 may expose top surfaces of the rear pads 166.

In general, in a structure in which the peripheral circuit structure and the cell structure are attached to each other by a bonding method, the common source layer may be formed on a top surface of the cell structure by a deposition method, and the laser annealing process may be performed to promote crystallization of the common source layer. However, heat caused by the laser annealing process could adversely affect structures formed in the connection region CON and the peripheral circuit connection region PRC. An input/output (I/O) plug and a through-stack plug may be formed in the connection region CON and the peripheral circuit connection region PRC so that a large top surface level difference could occur, and difficulty of an etching process of electrically isolating the common source layer, the I/O plug, and the through-stack plug from one another could be high.

However, according to the above-described embodiments, the insulating wall 140, the conductive base layer 142, and the cover insulating layer 144 may be in the connection region CON and the peripheral circuit connection region PRC to help prevent thermal damage from being applied to the structures formed in the connection region CON and the peripheral circuit connection region PRC while the laser annealing process of the common source layer 110 is performed in the cell region MCR. In an implementation, the first plug CP1 and the second plug CP2 may be surrounded by the insulating wall 140, the conductive base layer 142, and the ring insulation patterns 146 and 148 before the common source layer 110 may be formed, and undesired electrical connection between the common source layer 110 and the first and second plugs CP1 and CP2 may be prevented. Accordingly, the semiconductor device 100 may have improved electrical characteristics.

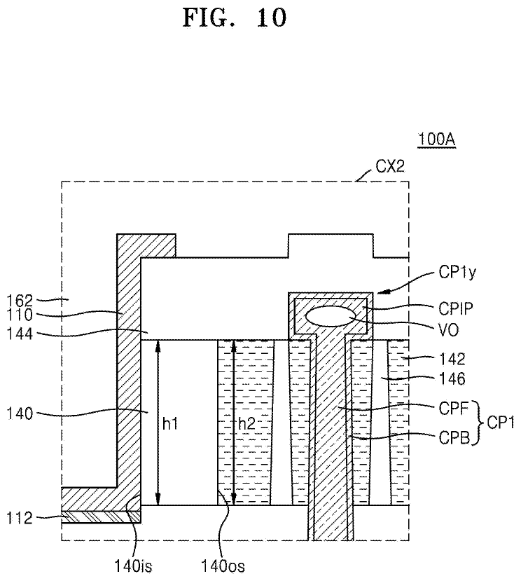

FIG. 10 is a cross-sectional view of a semiconductor device 100A according to embodiments.

Referring to FIG. 10, a second end CP1y of a first plug CP1 may further include a landing pad CP1P. The landing pad CP1P may have a shape extending or expanding in a horizontal direction to have a greater width than a part of the first plug CP1 surrounded by a conductive base layer 142. In an implementation, the landing pad CP1P of the first plug CP1 may be filled with a conductive filling layer CPF. In an implementation, the conductive filling layer CPF may not be completely filled in the landing pad CP1P and a void VO may be arranged.

In an implementation, as illustrated in FIG. 10, the landing pad CP1P may be on the top surface of the cover insulating layer 144 and the upper interlayer insulating layer 162 is arranged to cover top and side surfaces of the landing pad CP1P. In an implementation, a bottom surface of the landing pad CP1P may be at a vertical level lower than the top surface of the cover insulating layer 144, and a lower side of the sidewall of the landing pad CP1P may be surrounded by the cover insulating layer 144 and an upper side of the sidewall of the landing pad CP1P may be surrounded by the upper interlayer insulating layer 162.

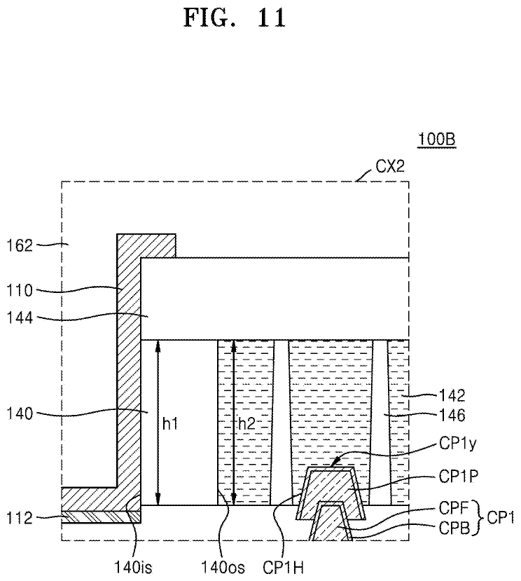

FIG. 11 is a cross-sectional view of a semiconductor device 100B according to embodiments.

Referring to FIG. 11, a second end CP1y of a first plug CP1 may further include a landing pad CP1P. The landing pad CP1P may be in an opening CP1H extending from a bottom surface of a conductive base layer 142 to the conductive base layer 142. The landing pad CP1P may not pass through the conductive base layer 142, and a top surface of the landing pad CP1P may be covered with the conductive base layer 142.

In an implementation, a part of the conductive base layer 142 may be removed to form the opening CP1H, the landing pad CP1P may be first formed in the opening CP1H, and a remaining part of the first plug CP1 may be formed in a subsequent process.

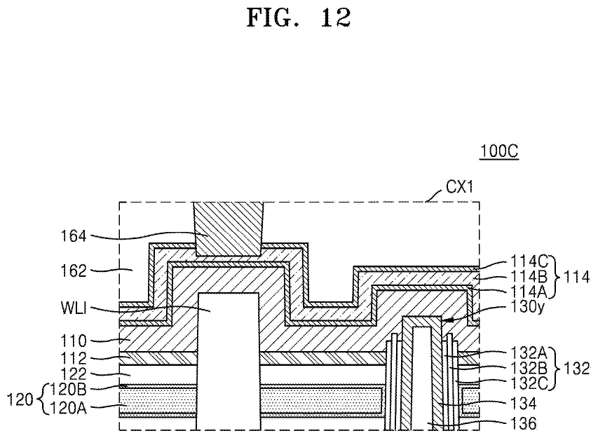

FIG. 12 is a cross-sectional view of a semiconductor device 100C according to embodiments.

Referring to FIG. 12, a conductive laminate 114 may be further on a top surface of a common source layer 110. The conductive laminate 114 may include a first conductive layer 114A, a second conductive layer 114B, and a third conductive layer 114C sequentially on the top surface of the common source layer 110. In an implementation, the first and third conductive layers 114A and 114C may include titanium nitride, tantalum nitride, tungsten nitride, or a combination thereof. The second conductive layer 114B may include a metal, e.g., W, molybdenum (Mo), chromium (Cr), Ni, Co, or Ta, a metal silicide such as tungsten silicide, nickel silicide, cobalt silicide, or tantalum silicide, or a combination thereof.

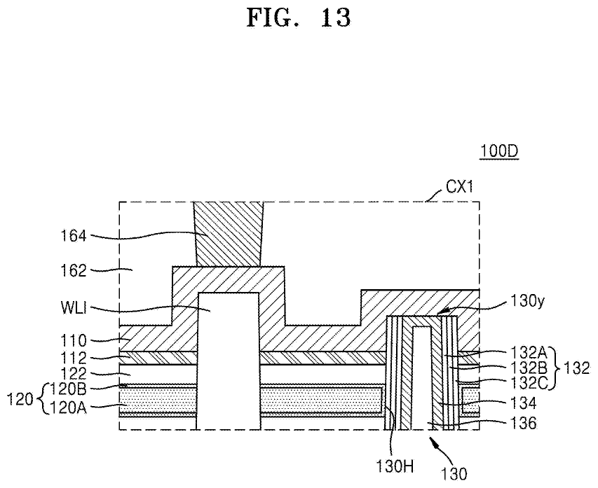

FIG. 13 is a cross-sectional view of a semiconductor device 100D according to embodiments.

Referring to FIG. 13, a second end 130y of a channel structure 130 may have a flat top surface level. A top surface of a channel layer 134 and a top surface of a gate insulating layer 132 may extend flat, and a common source layer 110 may cover the top surface of the channel layer 134 and the top surface of the gate insulating layer 132.

In an implementation, a channel hole 130H may be formed so that an end of the channel hole 130H is in a conductive base layer 142 in a cell region MCR, and the channel structure 130 may be formed in the channel hole 130H. Then, the second end 130y of the channel structure 130 in the conductive base layer 142 may be exposed by removing the conductive base layer 142 from the cell region MCR, and the top surface of the channel layer 134 may be exposed by removing a part of the gate insulating layer 132 covering the top surface of the channel layer 134 from the second end 130y. Then, a common source layer 110 covering the top surface of the channel layer 134 and the top surface of the gate insulating layer 132 may be formed. The top surface of the channel layer 134 and the top surface of the gate insulating layer 132 may be arranged flat according to etching characteristics of the process of removing a part of the gate insulating layer 132, so that a part of the common source layer 110 in contact with the top surface of the channel layer 134 and the top surface of the gate insulating layer 132 may also have a flat top surface level.

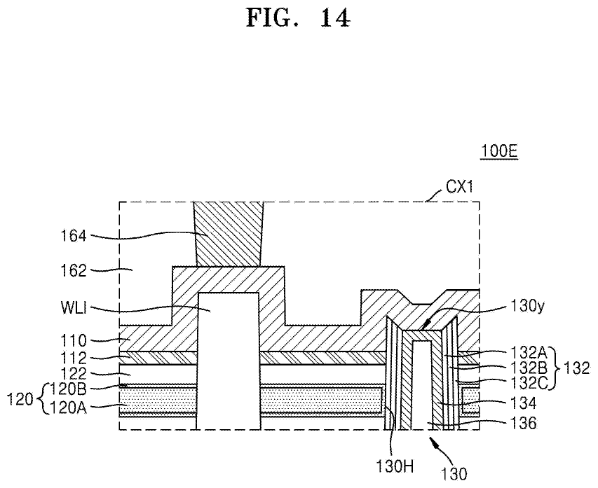

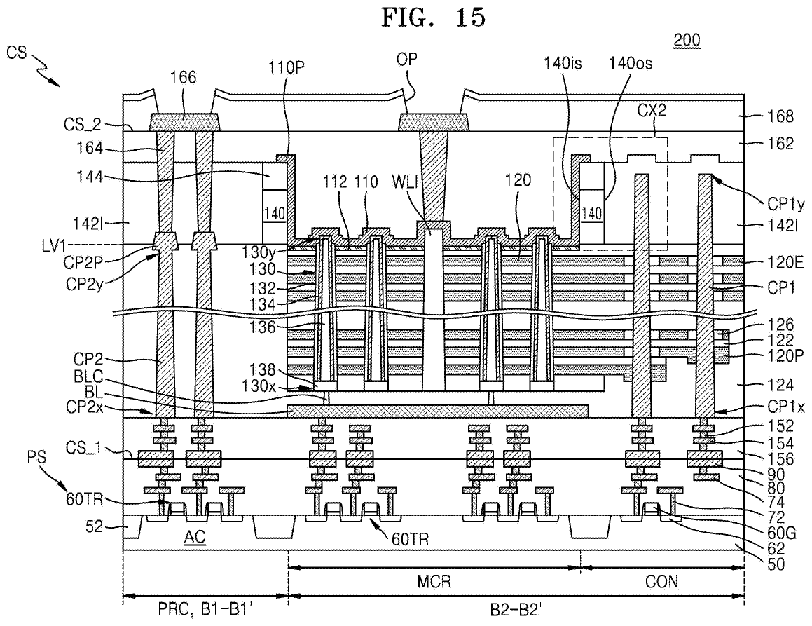

FIG. 14 is a cross-sectional view of a semiconductor device 100E according to embodiments.

Referring to FIG. 14, a second end 130y of a channel structure 130 may have a top surface level recessed downward. A top surface of a gate insulating layer 132 may be at a higher vertical level than a top surface of a channel layer 134, so that a part of a common source layer 110 in contact with the channel layer 134 may protrude toward the second end 130y of the channel structure 130.

In an implementation, in a process of exposing the top surface of the channel layer 134 by removing a part of the gate insulating layer 132 covering the top surface of the channel layer 134 from the second end 130y, according to etching characteristics of the removal process, the top surface of the gate insulating layer 132 may be at a higher vertical level than the top surface of the channel layer 134 so that the part of the common source layer 110 in contact with the channel layer 134 may protrude toward the second end 130y of the channel structure 130.

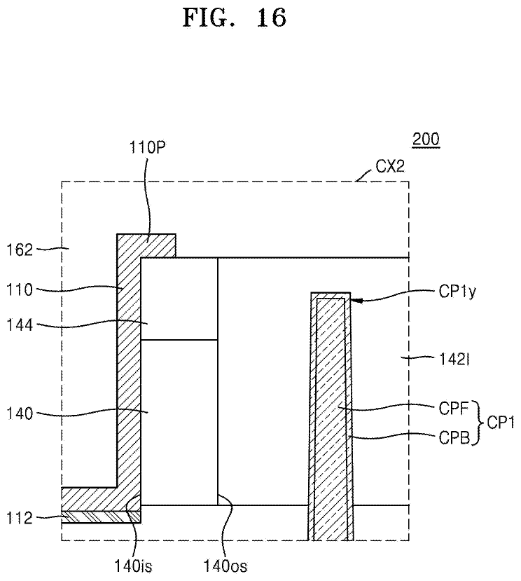

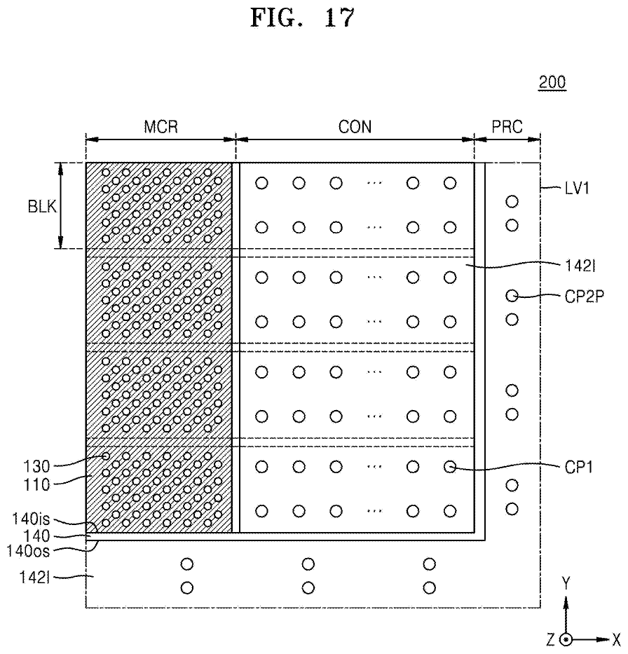

FIG. 15 is a cross-sectional view of a semiconductor device 200 according to embodiments. FIG. 16 is an enlarged view of the portion CX2 of FIG. 15. FIG. 17 is a horizontal cross-sectional view at the first vertical level LV1 of FIG. 15. The semiconductor device 200 described with reference to FIGS. 15 to 17 may be different from the semiconductor device 100 described with reference to FIGS. 3 to 9 in that the semiconductor device 200 includes an insulating base layer 142I instead of the conductive base layer 142.

Referring to FIGS. 15 to 17, the insulating base layer 142I may be in a connection region CON and a peripheral circuit connection region PRC, and may be on an external wall 140os of an insulating wall 140. A second end CP1y of a first plug CP1 may be covered with the insulating base layer 142I, and the ring insulation pattern 146 (refer to FIG. 6) around the first plug CP1 may not be formed. In an implementation, the insulating base layer 1421 may be formed to a height greater than that of the insulating wall 140, and a top surface of the insulating base layer 142I may be at the same level as a top surface of the cover insulating layer 144 on a top surface of the insulating wall 140. In an implementation, the insulating base layer 142I may include a silicon oxide layer, a silicon nitride layer, SiON, SiOCN, SiCN, or a combination thereof.

In manufacturing processes according to embodiments, a laser annealing process may be performed on a common source layer 110 in a state in which the insulating wall 140, the conductive base layer 142 (refer to FIG. 6), and the cover insulating layer 144 cover the connection region CON and the peripheral circuit connection region PRC. Then, a part of the cover insulating layer 144 and the conductive base layer 142 are removed, and the insulating base layer 1421 may be formed in a position from which the conductive base layer 142 is removed.

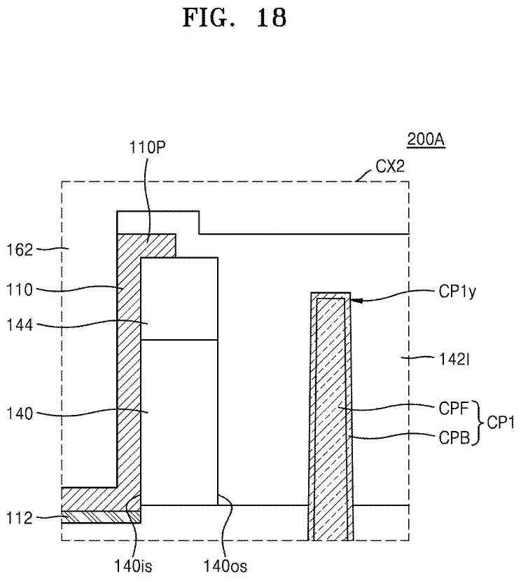

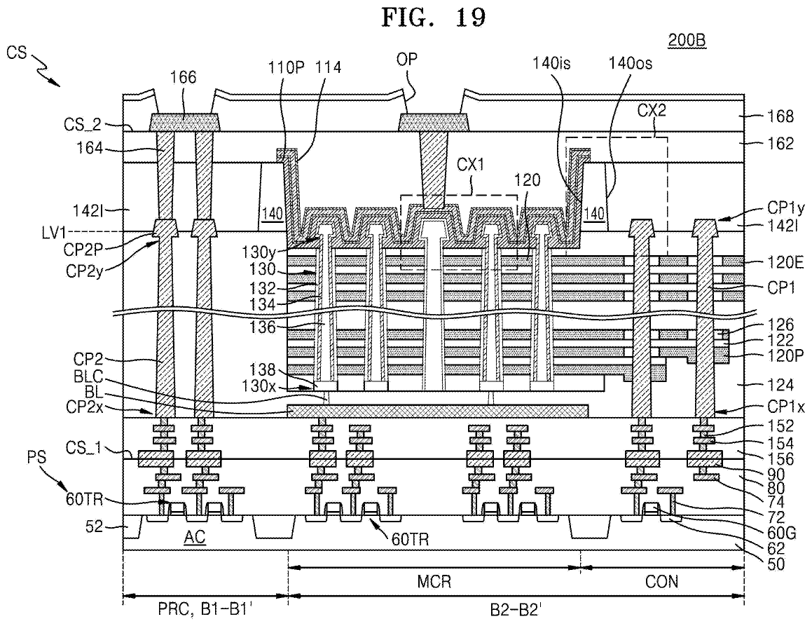

FIG. 18 is a cross-sectional view of a semiconductor device 200A according to embodiments.

Referring to FIG. 18, an insulating base layer 142I may be formed to a height large enough to cover a cover insulating layer 144, and a part of the insulating base layer 142I may be arranged on an edge portion 110P of a common source layer 110.

In manufacturing processes according to embodiments, a laser annealing process may be performed on the common source layer 110 in a state in which an insulating wall 140, the conductive base layer 142 (refer to FIG. 6), and the cover insulating layer 144 cover a connection region CON and a peripheral circuit connection region PRC. Then, a part of the cover insulating layer 144 and the conductive base layer 142 are removed, and the insulating base layer 142I may be formed in a position from which the conductive base layer 142 is removed. At this time, a part of the insulating base layer 142I may be formed to a thickness large enough to cover the edge portion 110P of the common source layer 110.

In an implementation, the insulating base layer 142I may be formed to a height less than that illustrated in FIG. 18 so as to cover a second end CP1y of a first plug CP1 and to have a top surface at a lower level than a top surface of the cover insulating layer 144.

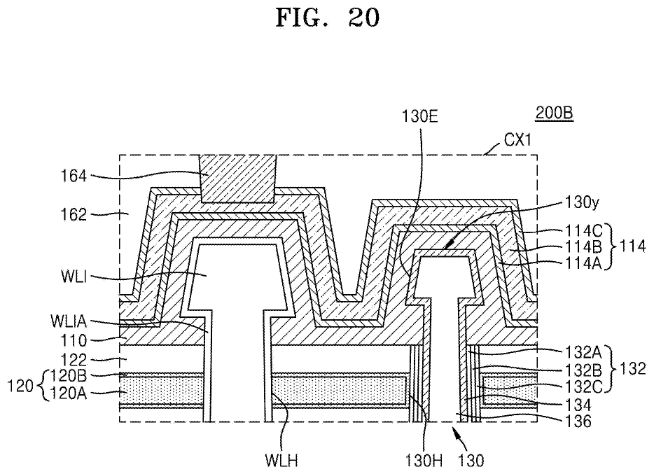

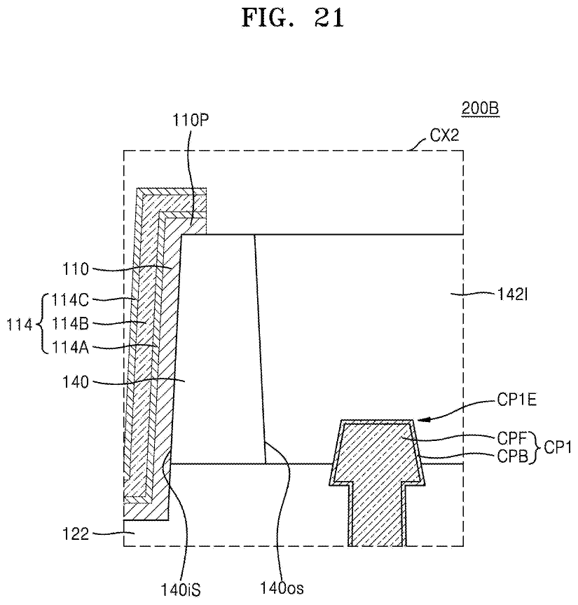

FIG. 19 is a cross-sectional view of a semiconductor device 200B according to embodiments. FIG. 20 is an enlarged view of the portion CX1 of FIG. 19. FIG. 21 is an enlarged view of the portion CX2 of FIG. 19.

Referring to FIGS. 19 to 21, a second end 130y of a channel structure 130 may include an extension 130E extending laterally with respect to a sidewall of the channel structure 130. For example, in the extension 130E, a channel layer 134 may extend laterally to have a relatively large width (for example, a part of the channel layer 134 arranged in the extension 130E may have a greater width than a part of the channel layer 134 at a lower level than the extension 130E). A top surface and a sidewall of the channel layer 134 arranged in the extension 130E may not be covered with a gate insulating layer 132, and may contact a common source layer 110.

In an implementation, an end of a stack isolation opening WLH may also have a shape extending laterally, and an insulating liner WLIA and a stack isolation insulating layer WLI may be arranged in the stack isolation opening WLH.

In an implementation, a second end CP1y of a first plug CP1 may include an extension CP1E. The extension CP1E may be formed to have a greater width than a remaining part of the first plug CP1. A top surface and a sidewall of the extension CP1E may be surrounded by an insulating base layer 142I.

In an implementation, the channel structure 130 may have the extension 130E, and the extension 130E may be formed to a relatively uniform height. Therefore, when the common source layer 110 is formed in the cell region MCR, a level difference of the common source layer 110 may be reduced so that the laser annealing process for the common source layer 110 may be precisely controlled.

In an implementation, as illustrated in FIGS. 19 to 21, the extension CP1E of the first plug CP1 may be surrounded by the insulating base layer 142I. In an implementation, as described with reference to FIGS. 3 to 9, the conductive base layer 142 (refer to FIG. 8) may be in a connection region CON and a peripheral circuit connection region PRC. In this case, the extension CP1E of the first plug CP1 may be surrounded by the conductive base layer 142, and the first ring insulation pattern 146 (refer to FIG. 8) may be arranged around the first plug CP1.

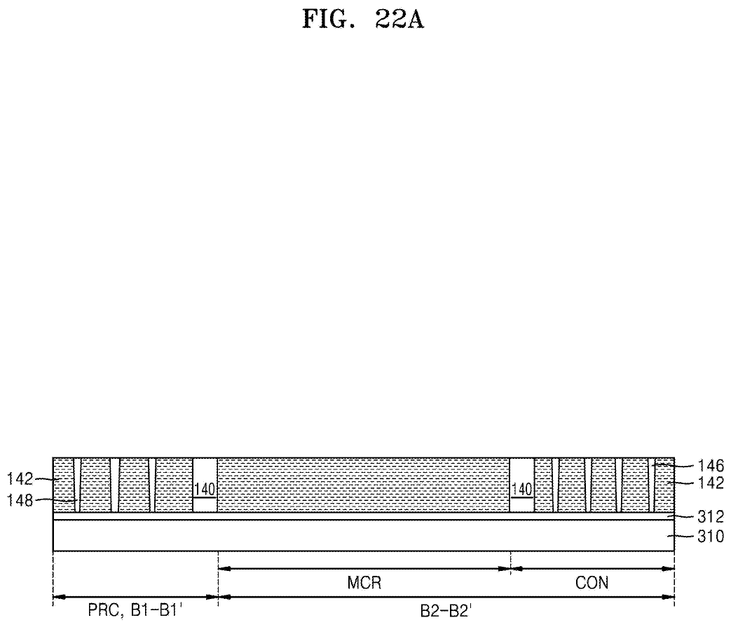

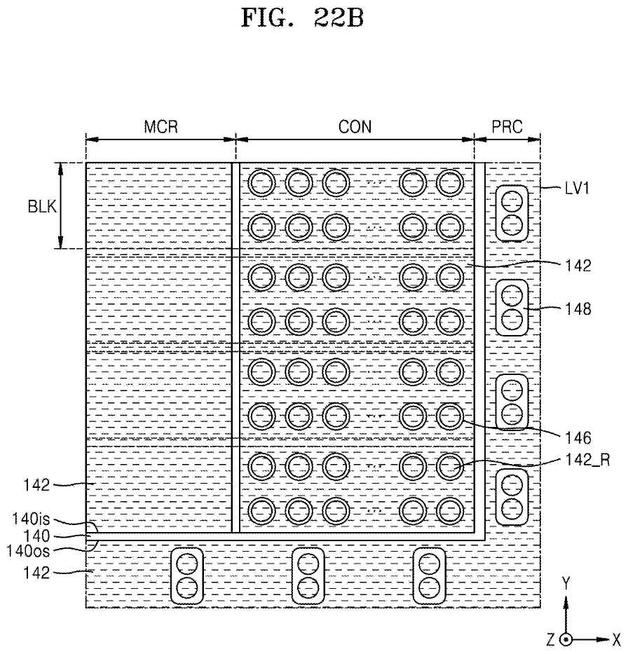

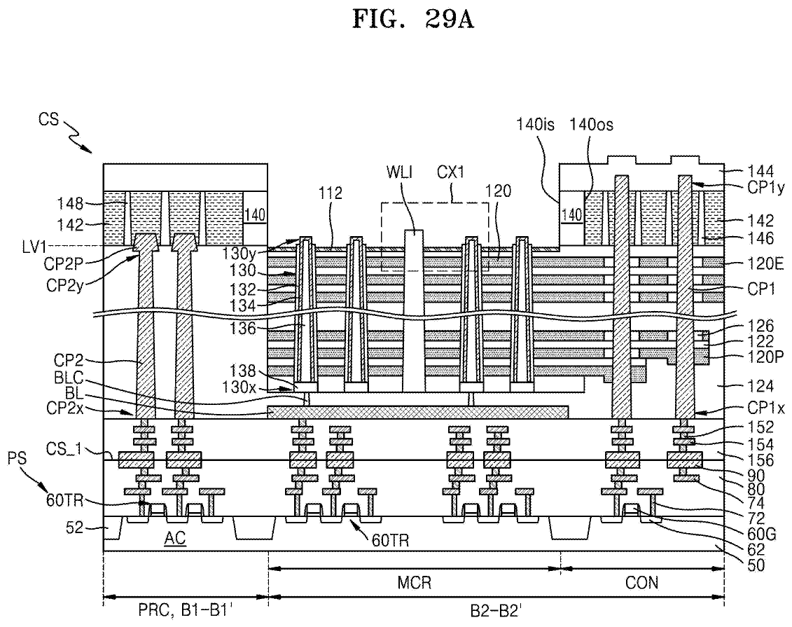

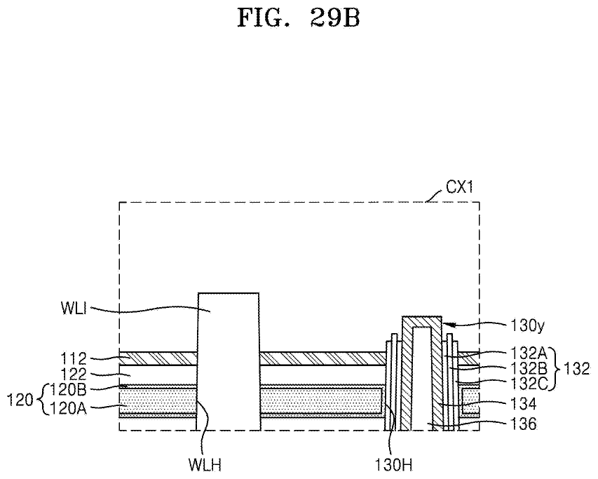

FIGS. 22A to 32 are schematic diagrams of stages in a method of manufacturing the semiconductor device 100 according to embodiments. Specifically, FIGS. 22A, 23 to 28, 29A, and 30 to 32 are cross-sectional views taken along the lines B1-B1′ and B2-B2′ of FIG. 6, FIG. 22B is a plan view of FIG. 22A, and FIG. 29B is an enlarged view of the portion CX1 of FIG. 29A.

Referring to FIGS. 22A and 22B, a buffer insulating layer 312 may be formed on a substrate 310, and the conductive base layer 142 may be formed on the buffer insulating layer 312.

In an implementation, the substrate 310 may include, e.g., Si, Ge, SiGe, gallium arsenic (GaAs), indium gallium arsenic (InGaAs), aluminum gallium arsenic (AlGaAs), or a mixture thereof. The buffer insulating layer 312 may include a combination of silicon oxide, a double layer of silicon oxide and titanium nitride, and a double layer of silicon oxide and silicon nitride.

In an implementation, the conductive base layer 142 may include polysilicon. The conductive base layer 142 may be formed to a height in a range of 50 nanometers to 1,000 nanometers. The cell region MCR, the connection region CON, and the peripheral circuit connection region PRC may be defined on the substrate 310, and the conductive base layer 142 may be formed at a uniform height over the cell region MCR, the connection region CON, and the peripheral circuit connection region PRC.

Then, a mask pattern may be formed on the conductive base layer 142, and a part of the conductive base layer 142 may be removed by using the mask pattern to form an opening 142H. After forming an insulating layer by using an insulating material in the opening 142H, an upper side of the insulating layer may be planarized to form the insulating wall 140, the first ring insulation pattern 146, and the second ring insulation pattern 148.

In an implementation, as illustrated in FIG. 22B, the insulating wall 140 may be formed at a boundary between the cell region MCR and the connection region CON, at a boundary between the cell region MCR and the peripheral circuit connection region PRC, or at a boundary between the connection region CON and the peripheral circuit connection region PRC.

The first ring insulation pattern 146 may be formed in the connection region CON, and may be formed to correspond to a position in which the first plug CP1 (refer to FIG. 6) is to be formed in a subsequent process. In an implementation, the first ring insulation pattern 146 may surround the first plug CP1 in a plan view and to be apart from the first plug CP1.

The second ring insulation pattern 148 may be formed in the peripheral circuit connection region PRC, and may be formed to correspond to a position in which the second plug CP2 (refer to FIG. 6) is to be formed in a subsequent process. In an implementation, the second ring insulation pattern 148 may surround the second plug CP2 in a plan view and to be apart from the second plug CP2. In an implementation, as illustrated in FIG. 22B, the second ring insulation pattern 148 may be formed to have a planar shape in which two ring shapes are merged.

Each of the first ring insulation pattern 146 and the second ring insulation pattern 148 may be formed to have a ring shape, and the first ring insulation pattern 146 may surround the ring 142_R of the conductive base layer 142, and the second ring insulation pattern 148 may surround the ring 142_R of the conductive base layer 142.

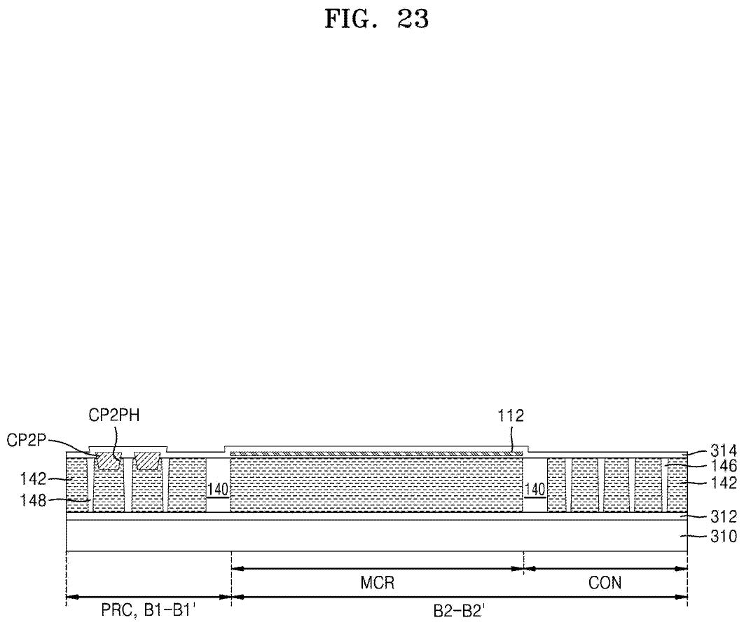

Referring to FIG. 23, a part of the conductive base layer 142 may be removed from the peripheral circuit connection region PRC to form a landing pad opening CP2PH, and the landing pad CP2P may be formed in the landing pad opening CP2PH. The landing pad CP2P may be formed in a position surrounded by the ring 142_R defined by the second ring insulation pattern 148.

Then, the etch stop layer 112 may be formed on the conductive base layer 142 in the cell region MCR. An insulating layer 314 may be formed between the etch stop layer 112 and the conductive base layer 142 and on a top surface of the etch stop layer 112. Accordingly, the conductive base layer 142 may be spaced apart from the etch stop layer 112 by the insulating layer 314. In an implementation, the etch stop layer 112 may include polysilicon.

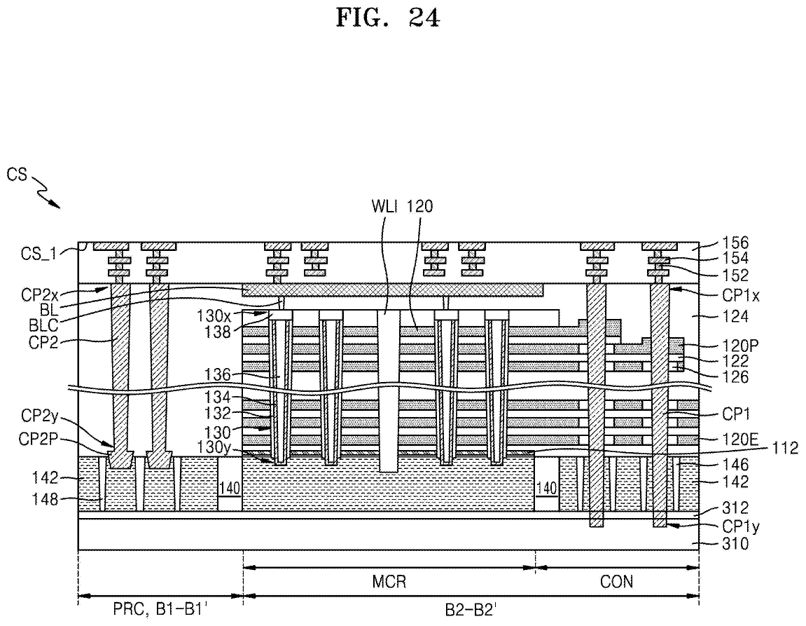

Referring to FIG. 24, the plurality of gate electrodes 120 and the plurality of mold insulating layers 122 may be formed in the cell region MCR and the connection region CON, and the plurality of extensions 120E and the plurality of pads 120P connected to the plurality of gate electrodes 120 may be formed in the connection region CON. In addition, the channel structure 130 extending in the vertical direction Z through the plurality of gate electrodes 120 and the bit line BL connected to the channel structure 130 may be formed in the cell region MCR. In addition, the first plug CP1 may be formed through the plurality of extensions 120E and the plurality of pads 120P in the connection region CON and the second plug CP2 may be formed through the stack insulating layer 124 in the peripheral circuit connection region PRC. In an implementation, the connection via 152, the connection wiring layer 154, and the interlayer insulating layer 156 electrically connected to the bit line BL, the first plug CP1, and the second plug CP2 may be formed.

In an implementation, in a process of forming the channel structure 130, the first end 130x of the channel structure 130 may be at a higher vertical level than the second end 130y of the channel structure 130, and the second end 130y of the channel structure 130 may be formed to extend to the conductive base layer 142 through the etch stop layer 112. For example, the second end 130y of the channel structure 130 may be at a lower vertical level than the top surface of the conductive base layer 142.

In an implementation, in a process of forming the first plug CP1, the first end CP1x of the first plug CP1 may be formed to a greater width than the second end CP1y of the first plug CP1, and the second end CP1y of the first plug CP1 may be formed to a height large enough to extend to the substrate 310 through the conductive base layer 142. In addition, the first plug CP1 may be formed in a position surrounded by the ring 142_R defined by the first ring insulation pattern 146.

In an implementation, in a process of forming the second plug CP2, the first end CP2x of the second plug CP2 may be formed to a greater width than the second end CP2y of the second plug CP2, and the second end CP2y of the second plug CP2 may be formed on the landing pad CP2P.

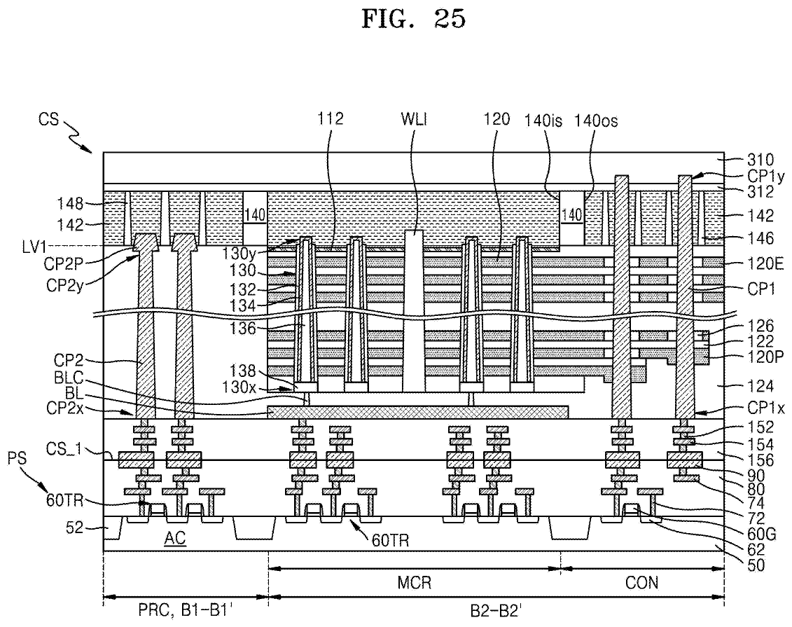

Referring to FIG. 25, the peripheral circuit structure PS may be prepared. The peripheral circuit structure PS may include the plurality of peripheral circuit transistors 60TR and the peripheral circuit wiring structure 70 arranged on the substrate 50. In the substrate 50, the active region AC may be defined by the device isolation layer 52 and the plurality of peripheral circuit transistors 60TR may be formed on the active region AC. Each of the plurality of peripheral circuit transistors 60TR may include the peripheral circuit gate 60G and the source/drain region 62 arranged in a part of the substrate 50 on both sides of the peripheral circuit gate 60G.

Then, the peripheral circuit structure PS may be attached to the cell structure CS. The peripheral circuit structure PS and the cell structure CS may be attached to each other by a metal-oxide hybrid bonding method through the plurality of connection pads 90 and the interlayer insulating layer 80 and the connection wiring layer 154.

Then, a structure in which the peripheral circuit structure PS and the cell structure CS are attached to each other may be reversed so that the substrate 310 faces upward.

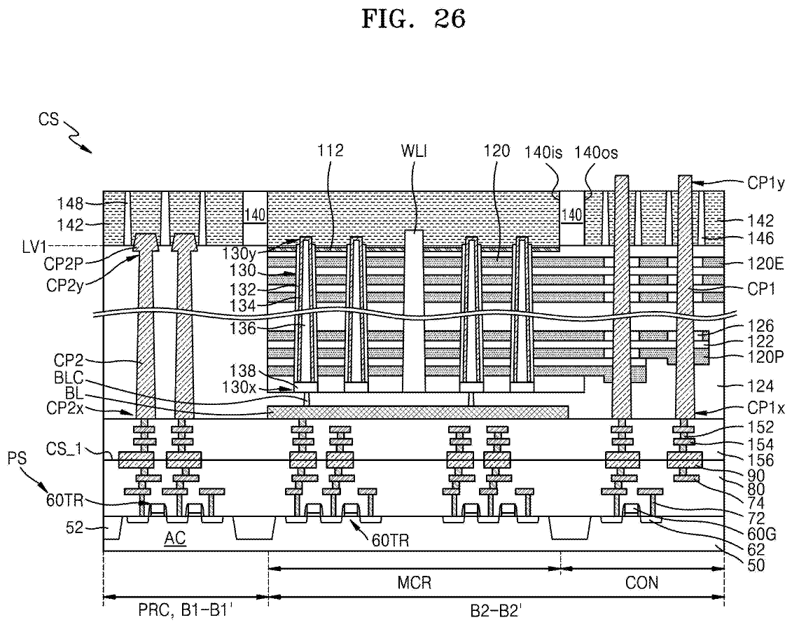

Referring to FIG. 26, the substrate 310 (refer to FIG. 25) may be removed. The substrate 310 may be removed by a grinding process and a subsequent etching process, and the buffer insulating layer 312 (refer to FIG. 25) may be exposed.

Then, the buffer insulating layer 312 may also be removed, and the top surface of the conductive base layer 142 and the top surface of the insulating wall 140 may be exposed. Here, the top surface of the conductive base layer 142 may contact the buffer insulating layer 312, and the bottom surface of the conductive base layer 142 may be adjacent to the channel structure 130.

As the buffer insulating layer 312 is removed, the second end CP1y of the first plug CP1 may protrude from the top surface of the conductive base layer 142.

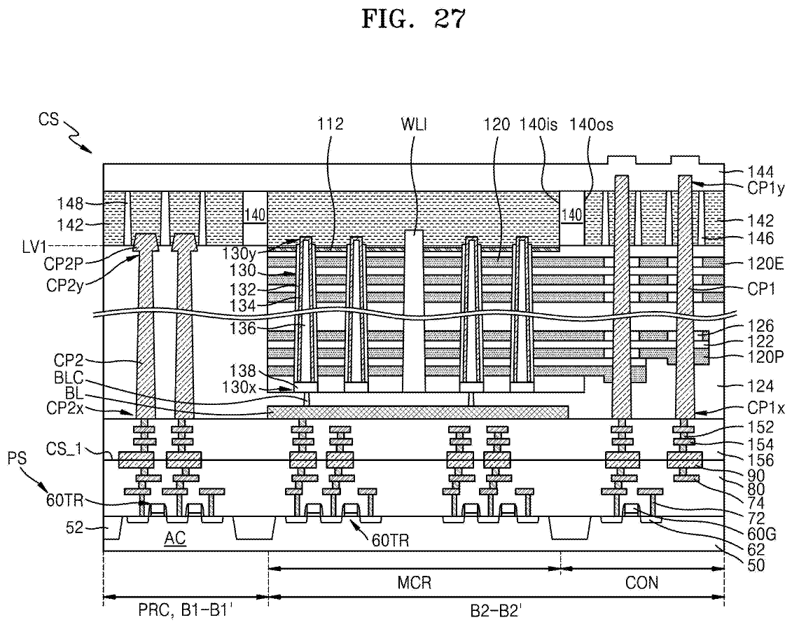

Referring to FIG. 27, the cover insulating layer 144 may be formed on the top surfaces of the conductive base layer 142 and the insulating wall 140. The cover insulating layer 144 may be formed to a height large enough to cover the second end CP1y of the first plug CP1. In an implementation, the cover insulating layer 144 may be formed to a height in a range of 50 nanometers to 300 nanometers. In an implementation, the cover insulating layer 144 may include a silicon oxide layer, a silicon nitride layer, SiON, SiOCN, SiCN, or a combination thereof. In an implementation, the cover insulating layer 144 may include a reflective layer having a stacked structure of alternately arranged silicon oxide layers and silicon nitride layers.

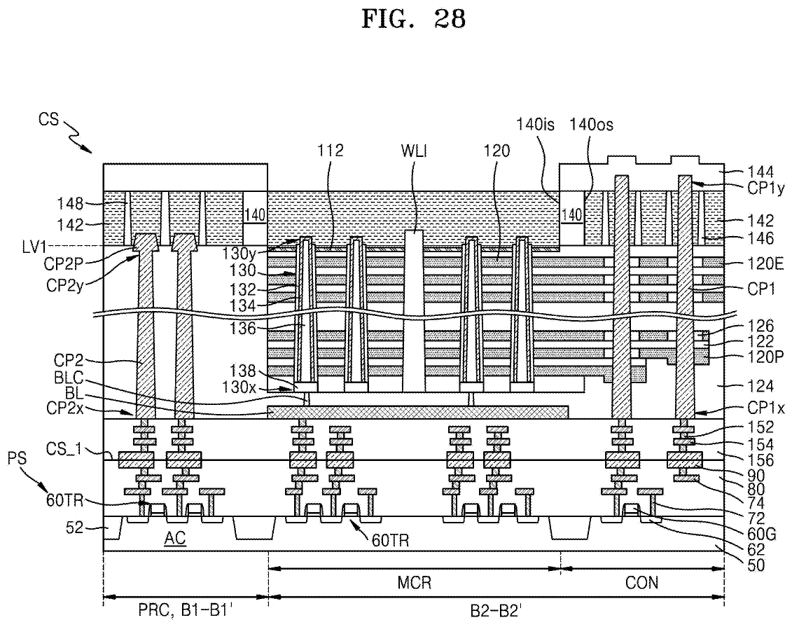

Referring to FIG. 28, a mask pattern may be formed on the cover insulating layer 144, and a part of the cover insulating layer 144 arranged in the cell region MCR may be removed. The top surface of the conductive base layer 142 arranged in the cell region MCR may be exposed by the removal process.

Referring to FIGS. 29A and 29B, the conductive base layer 142 arranged in the cell region MCR may be removed. The conductive base layer 142 arranged in the cell region MCR may be removed and the second end 130y of the channel structure 130 may be exposed.

In an implementation, the conductive base layer 142 in the cell region MCR and the conductive base layer 142 in the connection region CON may be physically separated from each other by the insulating wall 140, and the conductive base layer 142 arranged in the connection region CON may remain without being removed. In addition, the conductive base layer 142 in the cell region MCR and the conductive base layer 142 in the peripheral circuit connection region PRC may be physically separated from each other by the insulating wall 140, and the conductive base layer 142 in the peripheral circuit connection region PRC may remain without being removed.

Then, the top surface of the channel layer 134 may be exposed by removing the gate insulating layer 132 exposed to the second end 130y of the channel structure 130. The process of removing the gate insulating layer 132 may be performed until the top surface of the etch stop layer 112 is exposed. In an implementation, an upper side of the gate insulating layer 132 may be further removed so that the gate insulating layer 132 is at a lower level than the top surface of the channel layer 134 and the top surface and a part of the sidewall of the channel layer 134 are exposed.

In an implementation, in the process of removing the gate insulating layer 132, an upper side of the stack isolation insulating layer WLI may also be exposed to protrude to an upper side of the etch stop layer 112.

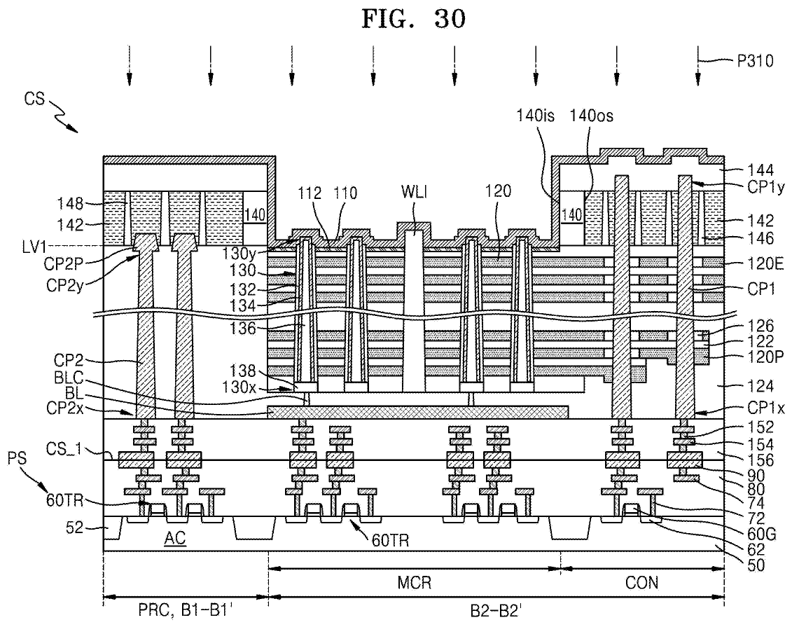

Referring to FIG. 30, the common source layer 110 may be formed on the cell region MCR, the connection region CON, and the peripheral circuit connection region PRC. The common source layer 110 may include polysilicon. In an implementation, the common source layer 110 may include polysilicon doped with n-type impurities.

In the cell region MCR, the common source layer 110 may be conformally formed on the exposed top surfaces of the etch stop layer 112 and the channel layer 134. In the connection region CON and the peripheral circuit connection region PRC, the common source layer 110 may be formed on the cover insulating layer 144. In an implementation, the common source layer 110 may be formed on the cover insulation layer 144 in the connection region CON and the peripheral circuit connection region PRC, and the common source layer 110 may not contact the first plug CP1 and the second plug CP2. In an implementation, as the common source layer 110 is formed on the relatively flat top surface of the cover insulating layer 144 in the connection region CON and the peripheral circuit connection region PRC, the common source layer 110 may have a relatively flat top surface level.

Then, the laser annealing process P310 may be performed on the common source layer 110. In an implementation, the laser annealing process P310 may help improve crystallinity of the common source layer 110 in the cell region MCR, may help increase the grain size of the common source layer 110, or may help reduce resistance of the common source layer 110. In an implementation, at least a part of the physical boundary between the etch stop layer 112 and the common source layer 110 may not be identified after the laser annealing process is performed.

Meanwhile, when the laser annealing process P310 is performed on the common source layer 110, the cover insulating layer 144 may function as an insulation barrier preventing heat caused by a laser from being transferred to the first plug CP1, the second plug CP2, and the landing pad CP2P arranged in the connection region CON and the peripheral circuit connection region PRC.

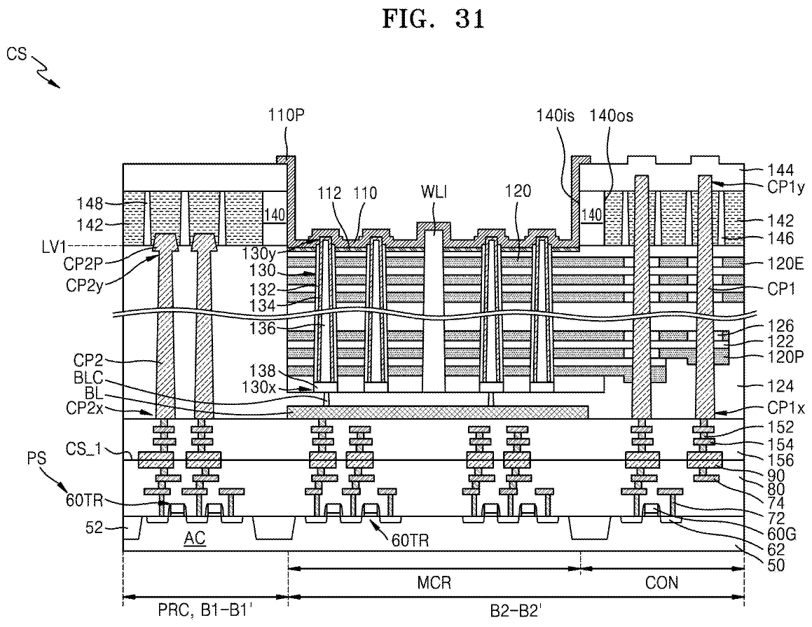

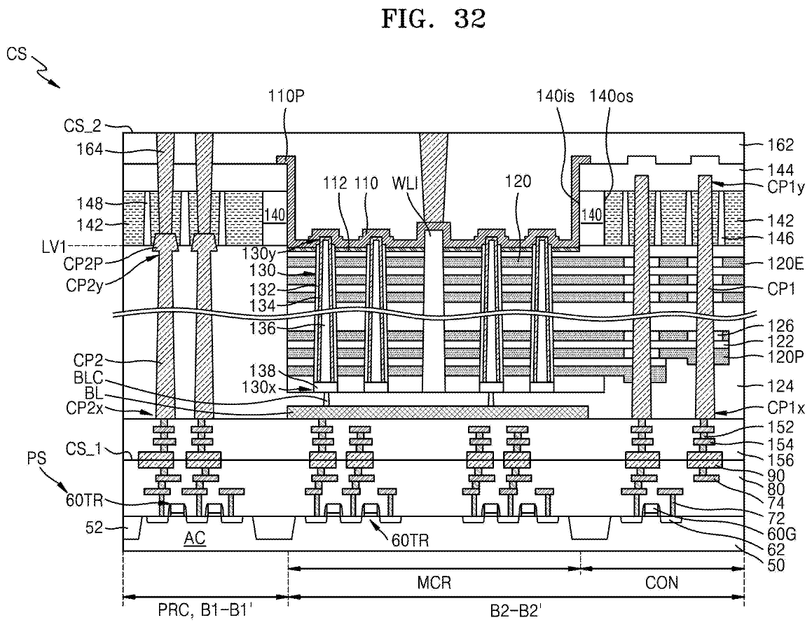

Referring to FIG. 31, the common source layer 110 in the connection region CON and the peripheral circuit connection region PRC may be removed. In an implementation, the common source layer 110 may be formed on the relatively flat top surface of the cover insulating layer 144 in the connection region CON and the peripheral circuit connection region PRC, and difficulty of the process of removing the common source layer 110 may be reduced. In addition, undesired electrical connection between the common source layer 110 and the first plug CP1, or undesired electrical connection between the common source layer 110 and the second plug CP2, which could otherwise occur when the conductive base layer 142 and the cover insulating layer 144 are not formed, may be prevented.

In an implementation, the edge portion 110P of the common source layer 110 may extend onto the insulating wall 140, e.g., onto the top surface of the cover insulating layer 144. Accordingly, a vertical level difference may occur between the central portion of the common source layer 110 and the edge portion 110P of the common source layer 110.

Referring to FIG. 32, the upper interlayer insulating layer 162 may be formed on the common source layer 110 and the cover insulating layer 144. Then, the rear vias 164 may be formed through the upper interlayer insulating layer 162. The rear vias 164 may be electrically connected to the landing pad LP2P and the common source layer 110.

Referring back to FIG. 6, the rear pads 166 connected to the rear vias 164 may be formed on the upper interlayer insulating layer 162. Then, the passivation layer 168 covering the rear pads 166 may be formed on the upper interlayer insulating layer 162, and an opening OP may be formed in the passivation layer 168 to expose the top surfaces of the rear pads 166.

According to the above-described embodiments, the insulating wall 140, the conductive base layer 142, and the cover insulating layer 144 may be in the connection region CON and the peripheral circuit connection region PRC to help prevent thermal damage from being applied to the structures formed in the connection region CON and the peripheral circuit connection region PRC while the laser annealing process of the common source layer 110 is performed in the cell region MCR. In addition, the first plug CP1 and the second plug CP2 may be surrounded by the insulating wall 140, the conductive base layer 142, and the ring insulation patterns 146 and 148 before the common source layer 110 is formed, and undesired electrical connection between the common source layer 110 and the first and second plugs CP1 and CP2 may be prevented. Accordingly, the semiconductor device 100 may have improved electrical characteristics.

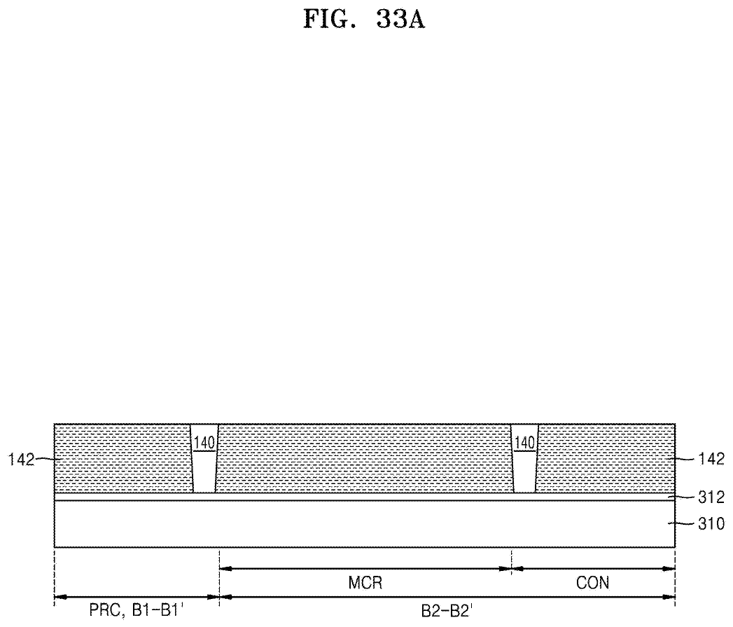

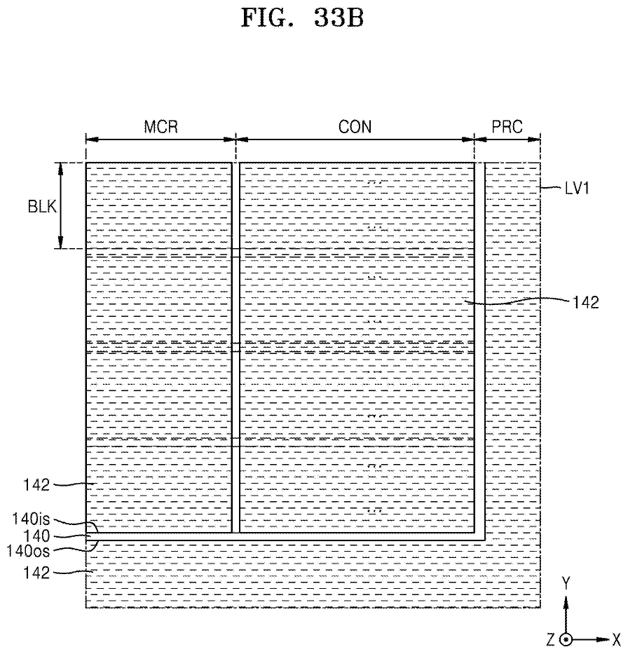

FIGS. 33A to 39 are cross-sectional views illustrating a method of manufacturing the semiconductor device 200 according to embodiments.

Referring to FIGS. 33A and 33B, the buffer insulating layer 312 and the conductive base layer 142 may be formed on the substrate 310, and then the insulating wall 140 may be formed.

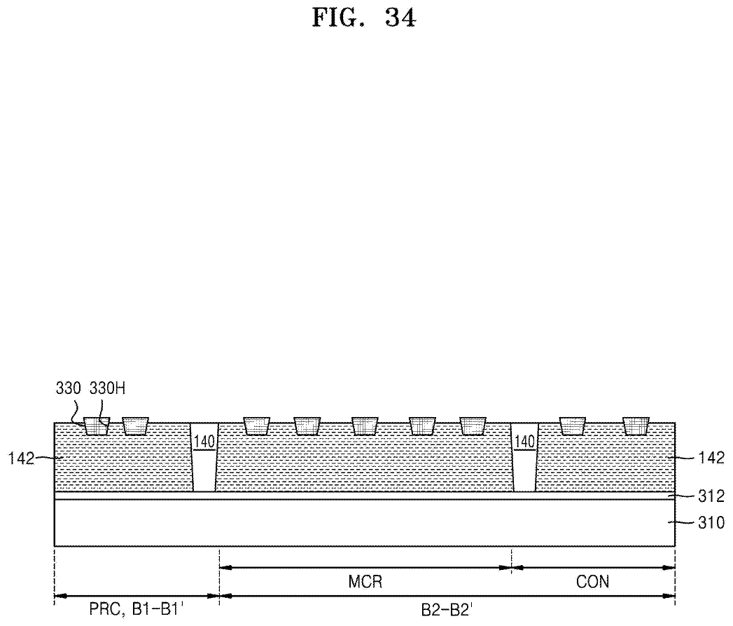

Referring to FIG. 34, a part of the conductive base layer 142 may be removed to form an opening 330H, and a sacrificial layer 330 may be formed in the opening 330H. The sacrificial layer 330 may include any one of a metal, silicon oxide, and silicon nitride.

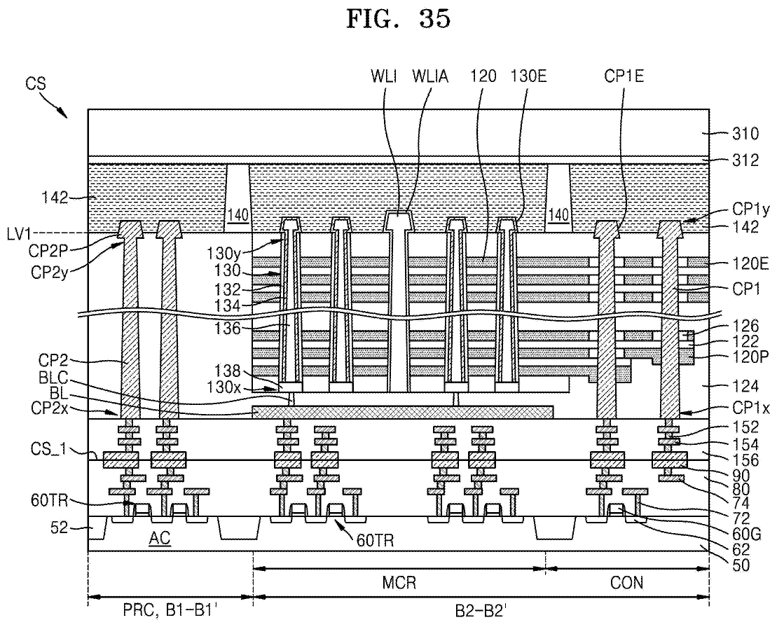

According to FIG. 35, a cell stack may be formed by alternately stacking the plurality of mold insulating layers 122 and the plurality of gate electrodes 120 on the conductive base layer 142 and the sacrificial layer 330, and the channel structure 130 extending in the vertical direction Z through the cell stack, the first plug CP1 extending in the vertical direction Z through the cell stack in the connection region CON, and the second plug CP2 extending in the vertical direction Z through the cell stack in the peripheral circuit connection region PRC may be formed.

In an implementation, in the process of forming the channel structure 130, the channel hole 130H extending in the vertical direction Z through the cell stack may land on the sacrificial layer 330. Then, the sacrificial layer 330 may be removed through the channel hole 130H, and the channel structure 130 may be formed in the channel hole 130H. A part of the channel structure 130 in the opening 330H may be defined as an extension 130E. Similarly, in the process of forming the first plug CP1, the first plug CP1 may land on the sacrificial layer 330 so that the extension CP1E may be formed in the first plug CP1.

Then, the cell structure CS may be completed and attached onto the peripheral circuit structure PS.

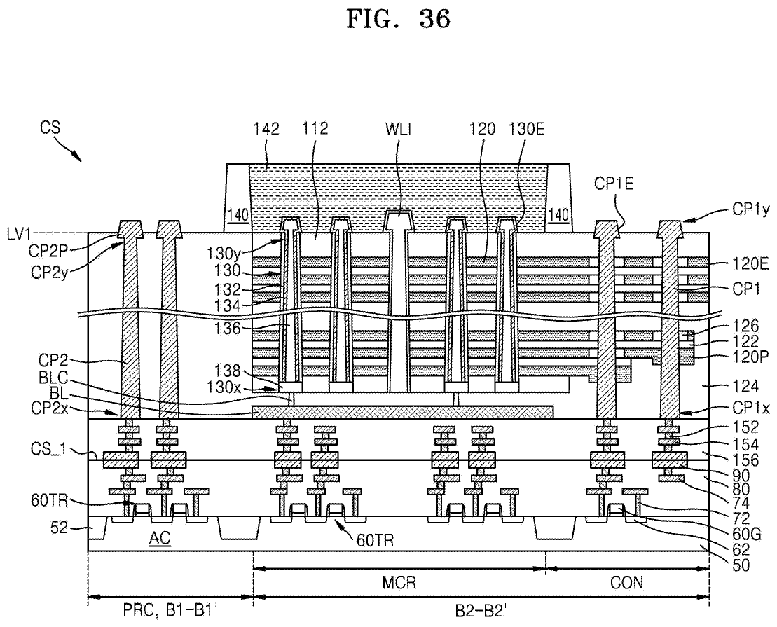

Referring to FIG. 36, the substrate 310 and the buffer insulating layer 312 may be removed and the top surface of the conductive base layer 142 may be exposed.

Then, a mask pattern may be formed on the conductive base layer 142 on the cell region MCR, and the conductive base layer 142 on the connection region CON and the peripheral circuit connection region PRC may be removed.

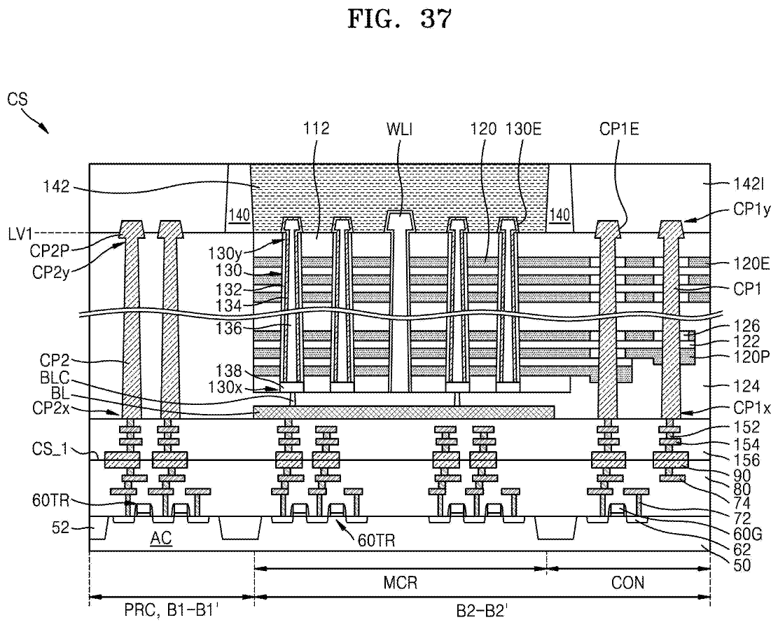

Referring to FIG. 37, the insulating base layer 1421 may be formed on the connection region CON and the peripheral circuit connection region PRC by using an insulating material. In embodiments, the insulating base layer 142I may have a top surface arranged on the same top surface as the conductive base layer 142.

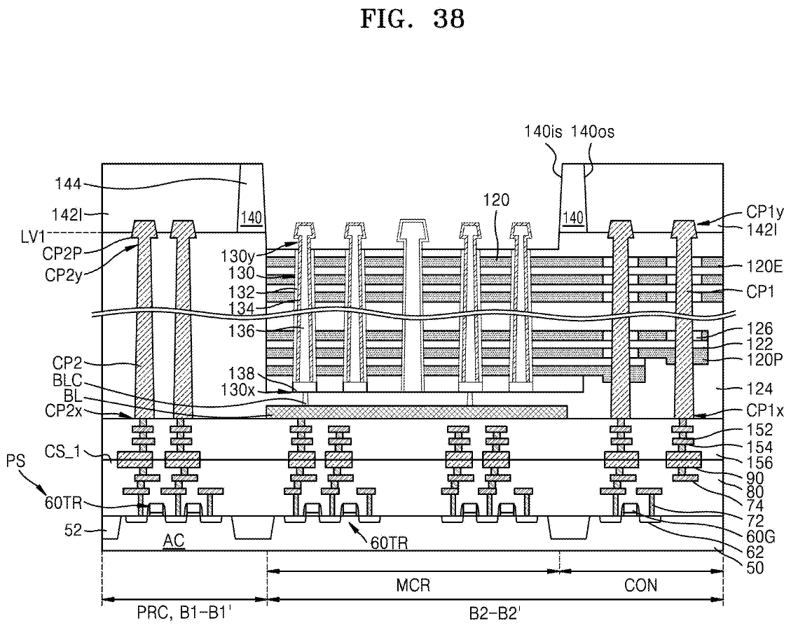

Referring to FIG. 38, the conductive base layer 142 may be removed from the cell region MCR and the second end 130y of the channel structure 130 may be exposed. In addition, the top surface of the channel layer 134 may be exposed by further removing the gate insulating layer 132 from the second end 130y of the channel structure 130. In an implementation, as illustrated in FIG. 38, both the top surface and the sidewall of the channel layer 134 in the expansion 130E may be exposed.

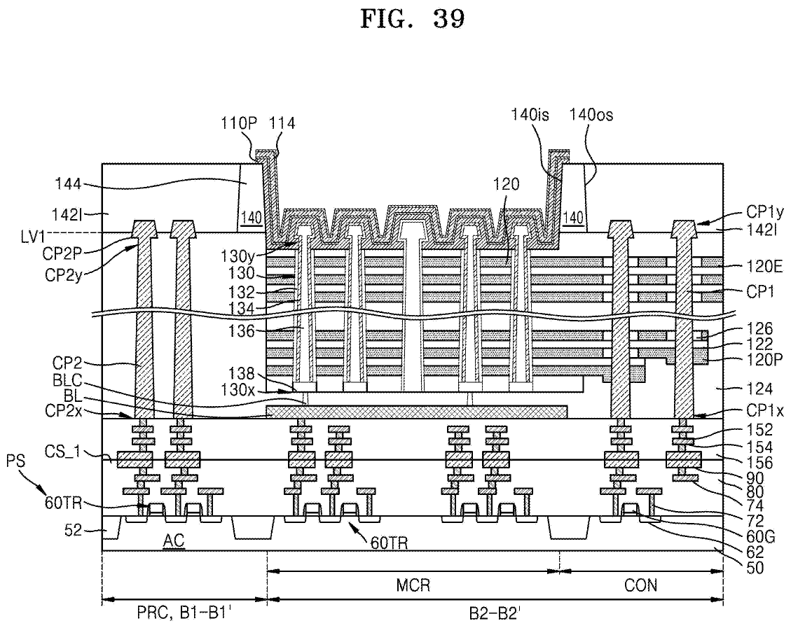

Referring to FIG. 39, the processes described with reference to FIGS. 30 and 31 may be performed to form the common source layer 110 electrically connected to the channel structure 130 on the cell region MCR.

Then, the semiconductor device 200B may be completed by performing the processes described with reference to FIG. 32.

According to the above-described embodiments, the insulating wall 140 and the insulating base layer 142I may be in the connection region CON and the peripheral circuit connection region PRC to help prevent thermal damage from being applied to the structures formed in the connection region CON and the peripheral circuit connection region PRC while the laser annealing process of the common source layer 110 is performed in the cell region MCR.

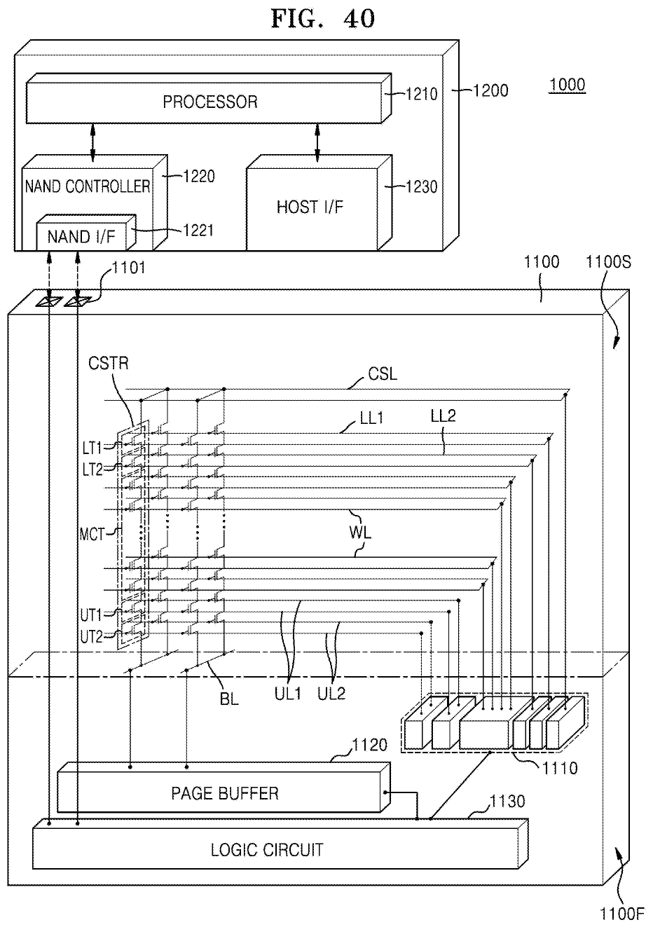

FIG. 40 is a diagram schematically illustrating a data storage system 1000 including a semiconductor device according to embodiments.

Referring to FIG. 40, the data storage system 1000 may include at least one semiconductor device 1100 and a memory controller 1200 electrically connected to the semiconductor device 1100. The data storage system 1000 may include, e.g., a solid state drive (SSD) device, a universal serial bus (USB), a computing system, a medical device, or a communication device including the at least one semiconductor device 1100.

The semiconductor device 1100 may include a non-volatile semiconductor device. For example, the semiconductor device 1100 may include a NAND flash semiconductor device including one of the semiconductor devices 10, 100, 100A, 100B, 100C, 100D, 100E, 200, 200A, and 200B described with reference to FIGS. 1 to 21. The semiconductor device 1100 may include a first structure 1100F and a second structure 1100S on the first structure 1100F. The first structure 1100F may include a peripheral circuit structure including a row decoder 1110, a page buffer 1120, and a logic circuit 1130.

The second structure 1100S may include a memory cell structure including a plurality of bit lines BL, a common source line CSL, a plurality of word lines WL, a plurality of string selection lines UL1 and UL2, a plurality of ground selection lines LL1 and LL2, and a plurality of memory cell strings CSTR between the plurality of bit lines BL and the common source line CSL.

In the second structure 1100S, each of the plurality of memory cell strings CSTR may include ground selection transistors LT1 and LT2 adjacent to the common source line CSL, string selection transistors UT1 and UT2 adjacent to the bit line BL, and a plurality of memory cell transistors MCT arranged between the ground selection transistors LT1 and LT2 and the string selection transistors UT1 and UT2. The number of ground selection transistors LT1 and LT2 and the number of string selection transistors UT1 and UT2 may be variously modified according to embodiments.

In an implementation, the plurality of ground selection lines LL1 and LL2 may be connected to gate electrodes of the ground selection transistors LT1 and LT2, respectively. The plurality of word lines WL may be connected to gate electrodes of the plurality of memory cell transistors MCT, respectively. The plurality of string selection lines UL1 and UL2 may be connected to gate electrodes of the string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The semiconductor device 1100 may communicate with the memory controller 1200 through input/output pads 1101 electrically connected to the logic circuit 1130. The input/output pads 1101 may be electrically connected to the logic circuit 130.

The memory controller 1200 may include a processor 1210, a NAND controller 1220, and a host interface 1230. In an implementation, the data storage system 1000 may include a plurality of semiconductor devices 1100, and in this case, the memory controller 1200 may control the plurality of semiconductor devices 1100.

The processor 1210 may control overall operations of the data storage system 1000 including the memory controller 1200. The processor 1210 may operate according to a predetermined firmware and may access the semiconductor device 1100 by controlling the NAND controller 1220. The NAND controller 1220 may include a NAND interface 1221 processing communication with the semiconductor device 1100. A control command for controlling the semiconductor device 1100, data to be written in the plurality of memory cell transistors MCT of the semiconductor device 1100, and data to be read from the plurality of memory cell transistors MCT of the semiconductor device 1100 may be transmitted through the NAND interface 1221. The host interface 1230 may provide a communication function between the data storage system 1000 and an external host. When the control command is received from the external host through the host interface 1230, the processor 1210 may control the semiconductor device 1100 in response to the control command.

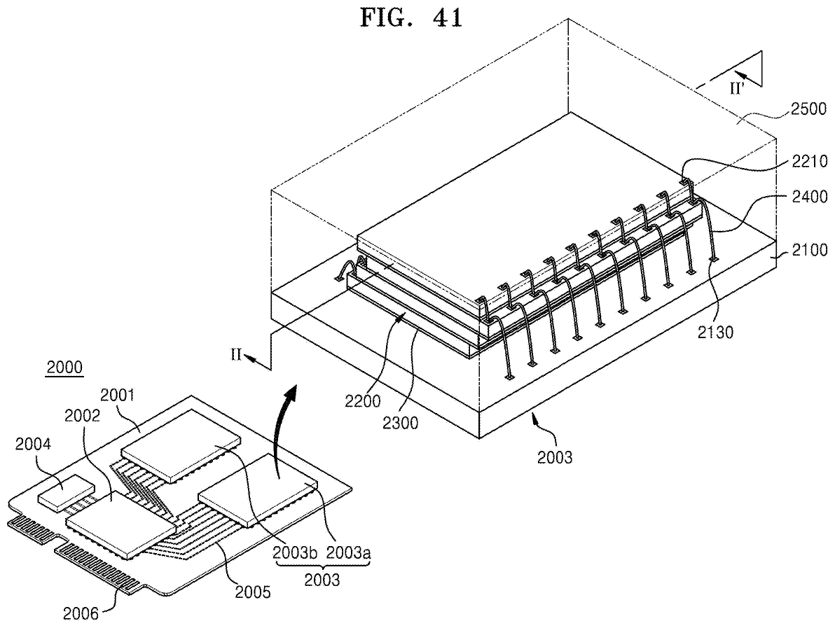

FIG. 41 is a perspective view schematically illustrating a data storage system 2000 including a semiconductor device according to embodiments.

Referring to FIG. 41, the data storage system 2000 according to an embodiment may include a main board 2001, a memory controller 2002 mounted on the main board 2001, at least one semiconductor package 2003, and dynamic random access memory (DRAM) 2004. The semiconductor package 2003 and the DRAM 2004 may be connected to the memory controller 2002 by a plurality of wiring patterns 2005 formed on the main board 2001.

The main board 2001 may include a connector 2006 including a plurality of pins coupled to an external host. The number and arrangement of pins in the connector 2006 may vary according to a communication interface between the data storage system 2000 and the external host. In an implementation, the data storage system 2000 may communicate with the external host according to any one of interfaces such as a universal serial bus (USB), peripheral component interconnect express (PCI-Express), serial advanced technology attachment (SATA), and M-Phy for universal flash storage (UFS). In an implementation, the data storage system 2000 may be operated by power supplied from the external host through connector 2006. The data storage system 2000 may further include a power management integrated circuit (PMIC) distributing power received from the external host to the memory controller 2002 and the semiconductor package 2003.

The memory controller 2002 may write or read data in or from the semiconductor package 2003 and may increase an operating speed of the data storage system 2000.

The DRAM 2004 may include a buffer memory for reducing a speed difference between the semiconductor package 2003 as a data storage and the external host. The DRAM 2004 included in the data storage system 2000 may also operate as a kind of cache memory, and may provide a space for temporarily storing data in a control operation for the semiconductor package 2003. When the DRAM 2004 is included in the data storage system 2000, the memory controller 2002 may further include a DRAM controller for controlling the DRAM 2004 in addition to the NAND controller 1220 for controlling the semiconductor package 2003.

The semiconductor package 2003 may include first and second semiconductor packages 2003a and 2003b apart from each other. Each of the first and second semiconductor packages 2003a and 2003b may include a plurality of semiconductor chips 2200. Each of the first and second semiconductor packages 2003a and 2003b may include a package substrate 2100, the plurality of semiconductor chips 2200 on the package substrate 2100, an adhesive layer 2300 arranged on a bottom surface of each of the plurality of semiconductor chips 2200, a plurality of connection structures 2400 electrically connecting the plurality of semiconductor chips 2200 to the package substrate 2100, and a molding layer 2500 covering the plurality of semiconductor chips 2200 and the plurality of connection structures 2400 on the package substrate 2100.

The package substrate 2100 may include a printed circuit board (PCB) including a plurality of package upper pads 2130. Each of the plurality of semiconductor chips 2200 may include input/output pads 2210. The input/output pads 2210 may correspond to the input/output pads 1101 of FIG. 40. Each of the plurality of semiconductor chips 2200 may include at least one of the semiconductor devices 10, 100, 100A, 100B, 100C, 100D, 100E, 200, 200A, and 200B described with reference to FIGS. 1 to 21.

In an implementation, the plurality of connection structures 2400 may include bonding wires electrically connecting the input/output pads 2210 to the plurality of package upper pads 2130. Therefore, in the first and second semiconductor packages 2003a and 2003b, the plurality of semiconductor chips 2200 may be electrically connected to one another in a bonding wire method, and may be electrically connected to the plurality of package upper pads 2130 of the package substrate 2100. In an implementation, in the first and second semiconductor packages 2003a and 2003b, the plurality of semiconductor chips 2200 may be electrically connected to one another by connection structures including through silicon vias (TSV) instead of the plurality of connection structures 2400 in the bonding wire method.

In an implementation, the memory controller 2002 and the plurality of semiconductor chips 2200 may be included in one package. In an embodiment, the memory controller 2002 and the plurality of semiconductor chips 2200 may be mounted on a separate interposer substrate different from the main board 2001, and the memory controller 2002 and the plurality of semiconductor chips 2200 may be connected to one another by wiring formed on the interposer substrate.

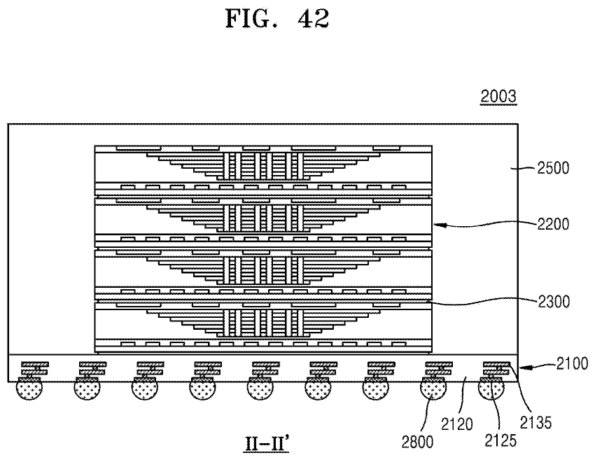

FIG. 42 is a cross-sectional view schematically illustrating a semiconductor package 2003 according to embodiments. FIG. 42 is a cross-sectional view taken along the line II-II′ of FIG. 41.

Referring to FIG. 42, in the semiconductor package 2003, the package substrate 2100 may include a PCB. The package substrate 2100 may include a package substrate body 2120, the plurality of package upper pads 2130 (refer to FIG. 41) arranged on a top surface of the package substrate body 2120, a plurality of lower pads 2125 arranged on or exposed through a bottom surface of the package substrate body 2120, and a plurality of internal wires 2135 electrically connecting the plurality of package upper pads 2130 (refer to FIG. 41) to the plurality of lower pads 2125 in the package substrate body 2120. As illustrated in FIG. 42, the plurality of package upper pads 2130 may be electrically connected to the plurality of connection structures 2400. As illustrated in FIG. 42, the plurality of lower pads 2125 may be connected to the plurality of wiring patterns 2005 on the main board 2001 of the data storage system 2000 illustrated in FIG. 41 through a plurality of conductive bumps 2800. Each of the plurality of semiconductor chips 2200 may include at least one of the semiconductor devices 10, 100, 100A, 100B, 100C, 100D, 100E, 200, 200A, and 200B described with reference to FIGS. 1 to 21.

One or more embodiments may provide a semiconductor device having a memory string arranged in a vertical direction.

One or more embodiments may provide a semiconductor device with high operating characteristics and improved integration.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a peripheral circuit structure; and
a cell structure stacked on the peripheral circuit structure and including a cell region, a connection region, and a peripheral circuit connection region,
wherein the cell structure includes:
gate electrodes spaced apart from one another in a vertical direction in the cell region;
a channel structure extending in the vertical direction through the gate electrodes, in the cell region, and including a first end and a second end opposite to the first end, the first end being proximate to the peripheral circuit structure;
an insulating wall extending in the vertical direction at a boundary between the cell region and the connection region; and
a common source layer connected to the second end of the channel structure in the cell region and having a portion arranged on a sidewall of the insulating wall.

2. The semiconductor device as claimed in claim 1, wherein the insulating wall surrounds the cell region in a plan view.

3. The semiconductor device as claimed in claim 1, wherein:
the channel structure further includes a cylindrical channel layer extending in the vertical direction, and
the channel layer arranged at the second end of the channel structure vertically overlaps and contacts the common source layer.

4. The semiconductor device as claimed in claim 1, wherein the cell structure further includes a conductive base layer arranged in the connection region and the peripheral circuit connection region, contacting the insulating wall, and having the same height as the insulating wall.

5. The semiconductor device as claimed in claim 4, wherein:
the cell structure further includes a cover insulating layer arranged on the conductive base layer and the insulating wall, and
an edge portion of the common source layer extends onto a top surface of the cover insulating layer.

6. The semiconductor device as claimed in claim 4, wherein the cell structure further includes:
a pad extending in the connection region from the gate electrodes and having a stepped shape;
a first plug extending in the connection region in the vertical direction through the pad and having a first end passing through the conductive base layer; and
a first ring insulation pattern passing through the conductive base layer, in the connection region, surrounding the first plug in a plan view, being apart from the first plug, and having an annular shape.

7. The semiconductor device as claimed in claim 4, wherein the cell structure further includes:
a second plug extending in the vertical direction in the peripheral circuit connection region and electrically connected to the peripheral circuit structure; and
a second ring insulation pattern passing through the conductive base layer, in the peripheral circuit connection region, surrounding the second plug in a plan view, being apart from the second plug, and having an annular shape.

8. The semiconductor device as claimed in claim 5, wherein:
the insulating wall includes a first end arranged close to the gate electrodes; and
a second end opposite to the first end, and
a width of the first end of the insulating wall in a first horizontal direction is greater than a width of the second end of the insulating wall in the first horizontal direction.

9. The semiconductor device as claimed in claim 8, wherein the cover insulating layer is arranged on the second end of the insulating wall.

10. The semiconductor device as claimed in claim 1, wherein the cell structure further includes an insulating layer arranged in the connection region and the peripheral circuit connection region, contacting the insulating wall, and having the same height as the insulating wall.

11. The semiconductor device as claimed in claim 10, wherein the cell structure further includes:
a pad extending from the gate electrodes, in the connection region, and having a stepped shape; and
a first plug extending in the vertical direction through the pad, in the connection region, and having a first end passing through the insulating layer.

12. A semiconductor device, comprising:
a peripheral circuit structure; and
a cell structure stacked on the peripheral circuit structure and including a cell region, a connection region, and a peripheral circuit connection region,
wherein the cell structure includes:
gate electrodes apart from one another in a vertical direction in the cell region;
a channel structure extending in the vertical direction through the gate electrodes, in the cell region, and including a first end and a second end opposite to the first end, the first end being arranged close to the peripheral circuit structure;
an insulating wall extending in the vertical direction at a boundary between the cell region and the connection region, and having an external wall and an internal wall;
a conductive base layer arranged in the connection region and the peripheral circuit connection region and contacting the external wall of the insulating wall; and
a common source layer arranged in the cell region, connected to the second end of the channel structure, and having an edge portion arranged on the internal wall of the insulating wall.

13. The semiconductor device as claimed in claim 12, wherein:
the channel structure further includes a cylindrical channel layer extending in the vertical direction, and
the channel layer arranged at the second end of the channel structure vertically overlaps and contacts the common source layer.

14. The semiconductor device as claimed in claim 12, wherein:
the cell structure further includes a cover insulating layer arranged on the conductive base layer and the insulating wall, and
the edge portion of the common source layer extends onto a top surface of the cover insulating layer.

15. The semiconductor device as claimed in claim 14, wherein the cell structure further includes:
a pad extending from the gate electrodes, in the connection region, and having a stepped shape;
a first plug extending in the vertical direction through the pad, in the connection region, and having a first end passing through the conductive base layer and the cover insulating layer; and
a first ring insulation pattern passing through the conductive base layer and the cover insulating layer, in the connection region, surrounding the first plug in a plan view, being apart from the first plug, and having an annular shape.

16. The semiconductor device as claimed in claim 14, wherein the cell structure further includes:
a second plug extending in the vertical direction in the peripheral circuit connection region and electrically connected to the peripheral circuit structure; and
a second ring insulation pattern passing through the conductive base layer and the cover insulating layer, in the peripheral circuit connection region, surrounding the second plug in a plan view, being apart from the second plug, and having an annular shape.

17. The semiconductor device as claimed in claim 12, wherein:
the common source layer is arranged over an entire area of the cell region, and
a first portion of the common source layer, connected to the channel structure, is at a vertical level lower than the edge portion of the common source layer.

18. A semiconductor device, comprising:
a peripheral circuit structure; and
a cell structure stacked on the peripheral circuit structure and including a cell region, a connection region, and a peripheral circuit connection region, wherein the cell structure includes:
gate electrodes apart from one another in a vertical direction in the cell region;
a channel structure extending in the vertical direction through the gate electrodes, in the cell region, and including a first end and a second end opposite to the first end, the first end being arranged close to the peripheral circuit structure;
a pad extending from the gate electrodes, in the connection region, and having a stepped shape;
an insulating wall extending in the vertical direction at a boundary between the cell region and the connection region and having an external wall and an internal wall;
a conductive base layer arranged in the connection region and the peripheral circuit connection region and contacting the external wall of the insulating wall;
a common source layer arranged in the cell region, connected to the second end of the channel structure, and having an edge portion arranged on the internal wall of the insulating wall;
a first plug extending in the vertical direction through the pad, in the connection region, and having a first end passing through the conductive base layer; and
a first ring insulation pattern passing through the conductive base layer and a cover insulating layer, in the connection region, surrounding the first plug in a plan view, being apart from the first plug, and having an annular shape.

19. The semiconductor device as claimed in claim 18, wherein:
the common source layer is arranged over an entire area of the cell region, and
the insulating wall surrounds the cell region in a plan view.

20. The semiconductor device as claimed in claim 18, wherein:
the channel structure further comprises a cylindrical channel layer extending in the vertical direction,
the channel layer arranged at the second end of the channel structure vertically overlaps and contacts a first portion of the common source layer, and
the first portion of the common source layer is at a vertical level lower than the edge portion of the common source layer.
